(19) United States
(12) Patent Application Publication
(10) Pub. No.: US 2026/0148582 A1
(43) Pub. Date: May 28, 2026

(54) DISPLAY DEVICE AND ELECTRONIC DEVICE INCLUDING THE SAME

(71) Applicant: Samsung Display Co., Ltd., Yongin-si (KR)

(72) Inventors: Goeen JEONG, Yongin-si (KR); TAEKYUNG AHN, Yongin-si (KR); Soo Yeong HONG, Yongin-si (KR); Seoyoung LIM, Yongin-si (KR)

(21) Appl. No.: 19/344,258

(22) Filed: Sep. 29, 2025

(30) Foreign Application Priority Data
Nov. 25, 2024 (KR) 10-2024-0169513

(51) Int. Cl. G06V 40/13; G06F 3/042; G06V 40/12; G09G 3/20; G09G 3/3233

(52) U.S. Cl. CPC G06V 40/1318; G06F 3/042; G06V 40/1359; G09G 3/3233; G09G 3/2074; G09G 2300/0452; G09G 2300/0804; G09G 2300/0819; G09G 2300/0842; G09G 2300/0861; G09G 2310/06; G09G 2310/08; G09G 2320/0233; G09G 2320/0238; G09G 2320/028; G09G 2320/066; G09G 2354/00; G09G 2358/00; G09G 2360/148

(57) ABSTRACT

A display device includes a window, and a display module including a base layer including first and second areas, a first group of light-emitting elements the first area to be deactivated during a first operation mode, and activated during a second operation mode, a second group of light-emitting elements in the second area to be activated during the first and second operation modes, a first light-sensing element between the first and second groups, a first light-blocking layer defining a first opening corresponding to the first group, a second opening corresponding to the second group, and a third opening corresponding to the first light-sensing element, and a second light-blocking layer above the first light-blocking layer, apart from the first area in plan view, overlapping the second area, and defining a fourth opening corresponding to the second opening.

### CROSS-REFERENCE TO RELATED APPLICATION

The present application claims priority to, and the benefit of, Korean Patent Application No. 10-2024-0169513, filed on Nov. 25, 2024, in the Korean Intellectual Property Office, the entire disclosure of which is incorporated herein by reference.

### BACKGROUND

### 1. Field

The present disclosure relates to a display device for operating in two modes and for recognizing biometric information, and an electronic device including the display device.

### 2. Description of the Related Art

Electronic devices, such as smart phones, tablet computers, notebook computers, car navigation units, and smart televisions, are being developed. These electronic devices include a display device to provide information.

Users seek that the quality of images matches their usage conditions. For instance, a brighter image is suitable when the electronic devices are used outdoors under the influence of natural light. In addition, when the electronic devices display personal information, an image with a narrow viewing angle is suitable.

In addition, display devices provide a variety of functions to organically interact with users, such as displaying images to provide information or detecting user's input. Recent display devices include various functions for detecting user's biometric information.

As the biometric information recognition methods, a capacitive method that detects a variation in capacitance formed between electrodes, an optical method that detects an incident light using an optical sensor, an ultrasonic method that detects a vibration using a piezoelectric material, or the like are used.

### SUMMARY

The present disclosure provides a display device with improved sensing performance of a sensor for biometric information recognition and an electronic device including the display device.

Embodiments of the present disclosure provide a display device including a window, and a display module below the window, and including a base layer including a first area and a second area including a light-emitting area and a peripheral area, a first group of light-emitting elements in the light-emitting area of the first area, and configured to be deactivated during a first operation mode, and to be activated during a second operation mode, a second group of light-emitting elements in the light-emitting area of the second area, and configured to be activated during the first operation mode and the second operation mode, a first light-sensing element between the first group of the light-emitting elements and the second group of the light-emitting elements, a first light-blocking layer defining a first opening corresponding to the first group of the light-emitting elements, a second opening corresponding to the second group of the light-emitting elements, and a third opening corresponding to the first light-sensing element, and a second light-blocking layer above the first light-blocking layer, apart from the first area in plan view, overlapping the second area, and defining a fourth opening corresponding to the second opening.

The first group of the light-emitting elements and the second group of the light-emitting elements may include a first light-emitting element configured to emit a first color light, a second light-emitting element spaced apart from the first light-emitting element in a first direction, and configured to emit a second color light, a third-first light-emitting element configured to emit a third color light, and a third-second light-emitting element configured to emit the third color light, and spaced apart from the third-first light-emitting element in a second direction crossing the first direction.

The first color light may be a blue light, the second color light is a red light, and the third color light is a green light.

The third-first light-emitting element may be spaced apart from the first light-emitting element in a diagonal direction crossing the first direction and the second direction, wherein the third-second light-emitting element is spaced apart from the second light-emitting element in the diagonal direction.

The first group of the light-emitting elements may be spaced apart from the second group of the light-emitting elements in a diagonal direction crossing the first direction and the second direction.

The first light-sensing element may be between the third-first light-emitting element of the first group of the light-emitting elements and the third-second light-emitting element of the second group of the light-emitting elements in the first direction.

The first light-sensing element may be between the second light-emitting element of the first group of the light-emitting elements and the first light-emitting element of the second group of the light-emitting elements in the second direction.

The first light-emitting element, the second light-emitting element, the third-first light-emitting element, and the third-second light-emitting element may include a first electrode, a second electrode, and a light-emitting pattern between the first electrode and the second electrode, wherein the display module includes a pixel definition layer defining display openings overlapping the first opening and the second opening and through which at least a portion of the first electrodes is exposed, the light-emitting patterns respectively being in the display openings.

The first light-sensing element may include a photoelectric conversion layer between a first electrode and a second electrode.

The display device may further include a second light-sensing element at a same layer as the first light-sensing element, wherein the first group of the light-emitting elements includes a first-first group of light-emitting elements and a first-second group of light-emitting elements arranged in the first direction from the first-first group of the light-emitting elements, wherein the second group of the light-emitting elements includes a second-first group of light-emitting elements and a second-second group of light-emitting elements arranged in the second direction from the second-first group of the light-emitting elements, wherein the first light-sensing element is between the first-first group of the light-emitting elements and the second-first group of the light-emitting elements, and wherein the second light-sensing element is between the first-second group of the light-emitting elements and the second-second group of the light-emitting elements.

The first light-sensing element may be electrically connected to the second light-sensing element.

The display module may include a color filter layer covering the first opening, the second opening, and the third opening, a thin film encapsulation layer covering the first group of the light-emitting elements, the second group of the light-emitting elements, and the first light-sensing element, and an insulating layer above the thin film encapsulation layer.

The display device may further include an input-sensing electrode between the thin film encapsulation layer and the insulating layer.

The first opening, the second opening, the third opening, and the fourth opening may have a circular shape or an oval shape.

The second light-blocking layer may define a fifth opening corresponding to the third opening.

The second light-blocking layer may include light-blocking patterns having a ring shape defining the fifth opening.

The second light-blocking layer may further include bridge patterns connecting the light-blocking patterns.

Embodiments of the present disclosure provide an electronic device including a window, a housing coupled with the window, and a display module between the window and the housing, and including a base layer including a first area and a second area including a light-emitting area and a peripheral area, a first group of light-emitting elements in the light-emitting area of the first area, and configured to be deactivated during a first operation mode, and to be activated during a second operation mode, a second group of light-emitting elements in the light-emitting area of the second area, and configured to be activated during the first operation mode and the second operation mode, a first light-sensing element between the first group of the light-emitting elements and the second group of the light-emitting elements, a first light-blocking layer defining a first opening corresponding to the first group of the light-emitting elements, a second opening corresponding to the second group of the light-emitting elements, and a third opening corresponding to the first light-sensing element, and a second light-blocking layer above the first light-blocking layer, spaced from the first area in plan view, overlapping the second area, and defining a fourth opening corresponding to the second opening.

The first group of the light-emitting elements and the second group of the light-emitting elements may include a first light-emitting element configured to emit a first color light, a second light-emitting element spaced apart from the first light-emitting element in a first direction, and configured to emit a second color light, a third-first light-emitting element configured to emit a third color light, and a third-second light-emitting element configure to emit the third color light, and spaced apart from the third-first light-emitting element in a second direction crossing the first direction.

The first group of the light-emitting elements may be spaced apart from the second group of the light-emitting elements in a diagonal direction crossing the first direction and the second direction.

According to the above, the display device provides an image with a narrow viewing angle in the first operation mode, and provides an image with a wide viewing angle in the second operation mode. The display device includes the first group of light-emitting elements that is deactivated in the first operation mode, and the second group of light-emitting elements that is activated in the first operation mode. The light-sensing element is positioned between the first group of the light-emitting elements and the second group of the light-emitting elements, and receives a substantially uniform amount of light regardless of its position.

According to the above, when a fingerprint sensor is used to detect a fingerprint, noise light is reduced, allowing the light-sensing element to more clearly receive light of different intensities corresponding to ridges and valleys of a fingerprint. As a result, the detection efficiency and reliability of the light-sensing element are improved.

### BRIEF DESCRIPTION OF THE DRAWINGS

FIG. 1A is a front view of an electronic device according to one or more embodiments of the present disclosure;

FIG. 1B is a perspective view of an electronic device according to one or more embodiments of the present disclosure;

FIG. 2 is an exploded perspective view of an electronic device according to one or more embodiments of the present disclosure;

FIG. 3 is a cross-sectional view of a display device according to one or more embodiments of the present disclosure;

FIG. 4 is a block diagram of a display device according to one or more embodiments of the present disclosure;

FIG. 5A is a circuit diagram of a pixel and a sensor according to one or more embodiments of the present disclosure;

FIG. 5B is a waveform diagram illustrating an operation of the pixel and the sensor shown in FIG. 5A;

FIG. 6A is a plan view of a portion of a display panel in a first operation mode according to one or more embodiments of the present disclosure;

FIG. 6B is a plan view of a portion of a display panel in a second operation mode according to one or more embodiments of the present disclosure;

FIG. 7 is an enlarged plan view of a portion of a display panel in the second operation mode according to one or more embodiments of the present disclosure;

FIG. 8A is a cross-sectional view taken along the line I-I′ of FIG. 7;

FIG. 8B is a cross-sectional view taken along the line II-II′ of FIG. 7;

FIG. 9A is a cross-sectional view taken along the line III-III′ of FIG. 7;

FIG. 9B is a cross-sectional view taken along the line IV-IV′ of FIG. 7; and

FIG. 10 is an enlarged plan view of a portion of a display panel in a second operation mode according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

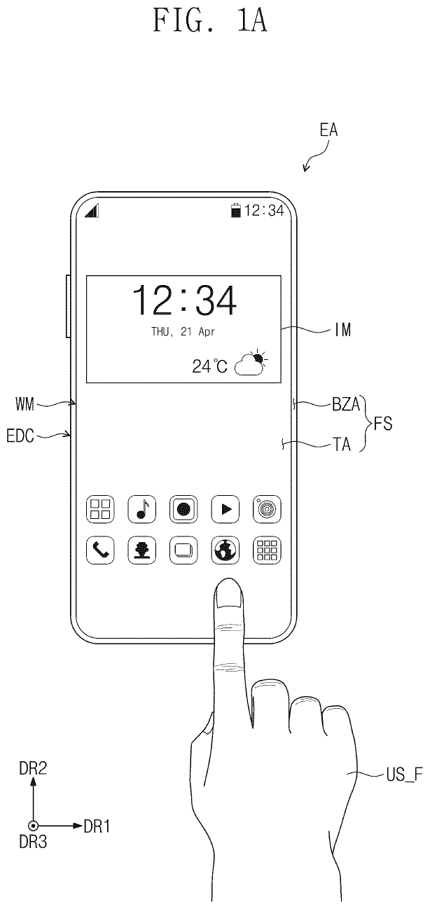

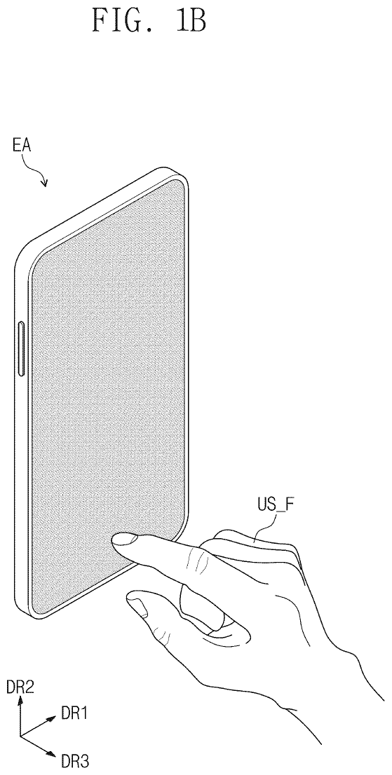

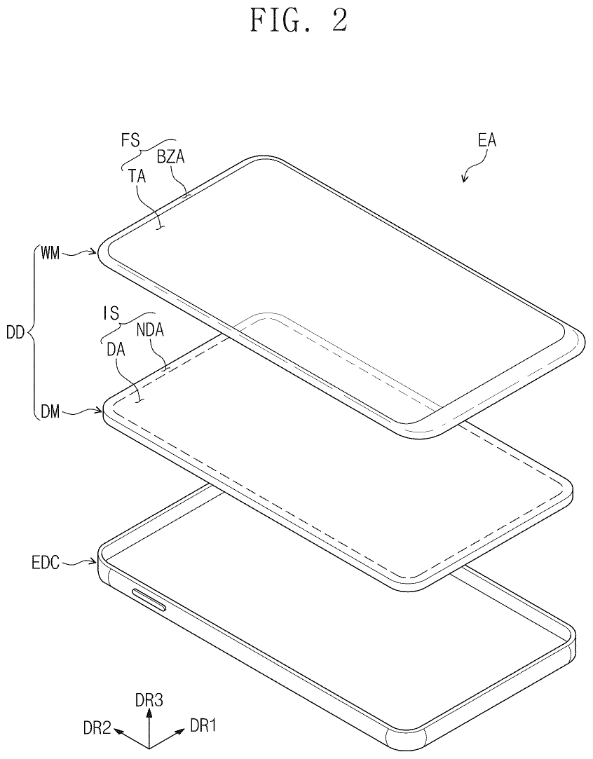

FIG. 1A is a front view of an electronic device EA according to one or more embodiments of the present disclosure. FIG. 1B is a perspective view of the electronic device EA according to one or more embodiments of the present disclosure. FIG. 2 is an exploded perspective view of the electronic device EA according to one or more embodiments of the present disclosure.

Referring to FIGS. 1A and 1B, the electronic device EA may have a rectangular shape with short sides parallel to a first direction DR1, and long sides parallel to a second direction DR2 crossing the first direction DR1. However, the shape of the electronic device EA should not be limited to the rectangular shape, and the electronic device EA may have a variety of shapes, such as a circular shape, a polygonal shape, or the like.

The electronic device EA may be activated in response to electrical signals. The electronic device EA may include, for example, at least one of a portable communication device (e.g., a smart phone), a computer device, a portable multimedia device, a portable medical device, a camera, a wearable device, or a home appliance. The electronic device EA according to the present disclosure should not be limited to the above-described devices. FIGS. 1A and 1B show a mobile phone as a representative example of the electronic device EA.

Hereinafter, a normal line direction, which is substantially perpendicular to a plane defined by the first direction DR1 and the second direction DR2, is referred to as a third direction DR3. In the following descriptions, the expression “when viewed in a plane” may mean a state of being viewed in the third direction DR3.

An upper surface of the electronic device EA may be defined as a display surface FS, and may be substantially parallel to the plane defined by the first direction DR1 and the second direction DR2. Images IM generated by the electronic device EA may be provided to a user through the display surface FS.

The display surface FS may be divided into a transmission area TA and a bezel area BZA. The images IM may be displayed through the transmission area TA. The user may view the images IM through the transmission area TA. The transmission area TA may have a quadrangular shape with rounded vertices. However, this is merely one example, and the transmission area TA may have a variety of shapes, and should not be particularly limited.

The bezel area BZA may be defined adjacent to the transmission area TA. The bezel area BZA may have a color. The bezel area BZA may surround the transmission area TA. Accordingly, the shape of the transmission area TA may be defined by the bezel area BZA, although this is merely one example. According to one or more embodiments, the bezel area BZA may be located adjacent to only one side of the transmission area TA, or may be omitted.

The electronic device EA may sense an external input applied thereto from the outside. The external input may include a variety of external inputs provided from the outside. For example, the external input may include an external input (e.g., a hovering input) detected when in proximity to or approaching close to the electronic device EA at a selected distance, as well as a touch input from a part of the user's body (e.g., a finger of the user US_F) or from a separate device (e.g., an active pen, a digitizer, or the like). In addition, the external input may take various forms, such as force, pressure, temperature, or light.

The electronic device EA may sense biometric information of the user, which is applied thereto from the outside. The electronic device EA may include a biometric information sensing area defined in the display surface FS to sense the biometric information of the user. The biometric information sensing area may be defined across an entire portion of the transmission area TA, or within a portion of the transmission area TA. FIG. 1A shows a structure in which the entire portion of the transmission area TA is used as the biometric information sensing area.

FIG. 1A is the front view of the electronic device EA that operates in a first operation mode (hereinafter, referred to as a first mode) or in a second operation mode (hereinafter, referred to as a second mode). FIG. 1B is a lateral perspective view of the electronic device EA that operates in the first mode. As an example, the second mode may be a normal mode in which the images IM are displayed at a first viewing angle, and the first mode may be a private mode in which the images IM are displayed at a second viewing angle that is narrower than the first viewing angle. The first viewing angle and the second viewing angle may be defined as angles at which images are viewed without a distortion of a display quality based on the normal line direction of the display surface FS.

Referring to FIG. 1A, when looking at the electronic device EA from the front (or in the direction parallel to the normal line direction or from the third direction DR3) in the first mode or the second mode, the images IM generated by the electronic device EA may be visible to the user. When looking at the electronic device EA at an angle exceeding the second viewing angle in the first mode, the images IM may not be visible.

The second viewing angle and a brightness at the second viewing angle in first mode may be set in various ways. When looking at the electronic device EA at the angle exceeding the second viewing angle in the second mode, the images IM may be visible to the user. As an example, the second viewing angle may be about 45 degrees, and the brightness at about 45 degrees may be about 10 percent of the maximum brightness. The brightness at about 45 degrees in the second mode may be greater than or equal to about 20 percent, although the present disclosure should not be limited thereto or thereby.

The electronic device EA may selectively operate in one of the second mode in which the images are displayed at the first viewing angle, or the first mode in which the images are displayed at the second viewing angle that is narrower than the first viewing angle. The switching between the first mode and the second mode may be set by the user, or may occur when a corresponding application is executed. As an example, when an application that involves a risk of exposing personal information is executed, such as a banking or memo application, the operation mode of the electronic device EA may be switched from the second mode to the first mode.

Referring to FIG. 2, the electronic device EA may include a display device DD and a housing EDC. The display device DD may include a window WM and a display module DM. The window WM may be located on the display module DM, and the housing EDC may be located under the display module DM (as used herein, “located on” may mean “above”). The window WM and the housing EDC may be coupled with each other to form the exterior of the display device DD.

A front surface of the window WM may define the display surface FS of the electronic device EA. The window WM may include an optically transparent insulating material. For example, the window WM may include a glass or plastic material. The window WM may have a single-layer or multi-layer structure. As an example, the window WM may include a plurality of plastic films coupled to each other by an adhesive or a glass substrate and a plastic film coupled to the glass substrate by an adhesive.

A front surface IS of the display module DM may include a display area DA corresponding to the transmission area TA, and a non-display area NDA corresponding to the bezel area BZA.

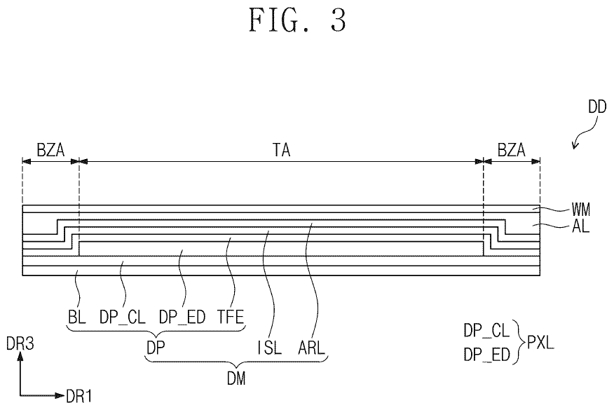

FIG. 3 is a cross-sectional view of the display device DD according to one or more embodiments of the present disclosure.

The display device DD according to the present disclosure may include the display module DM and the window WM, and the display module DM may include a display panel DP, an input-sensing layer ISL, and an anti-reflective layer ARL.

The display panel DP may display images in response to electrical signals, and the input-sensing layer ISL may sense external inputs applied from the outside. The external inputs may include a variety of external inputs provided from the outside. The anti-reflective layer ARL may include a plurality of color filters and a light-blocking pattern.

The display panel DP according to the present disclosure may be a light-emitting type display panel, although it should not be particularly limited. For instance, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include a quantum dot or a quantum rod. Hereinafter, the organic light-emitting display panel will be described as a representative example of the display panel DP.

Referring to FIG. 3, the display panel DP may include a base layer BL, a pixel layer PXL, and a thin film encapsulation layer TFE. The display panel DP may be a flexible display panel, although the present disclosure should not be limited thereto or thereby. As an example, the display panel DP may be a foldable display panel folded with respect to a folding axis or a rigid display panel.

The base layer BL may include a synthetic resin layer. The synthetic resin layer may be a polyimide-based resin layer, although a material for the synthetic resin layer should not be particularly limited. In addition, the base layer BL may include a glass substrate, a metal substrate, or an organic/inorganic composite material substrate.

The pixel layer PXL may be located on the base layer BL. The pixel layer PXL may include a circuit layer DP_CL and an element layer DP_ED. The circuit layer DP_CL may be located between the base layer BL and the element layer DP_ED. The circuit layer DP_CL may include at least one insulating layer and a circuit element. Hereinafter, the insulating layer included in the circuit layer DP_CL is referred to as an intermediate insulating layer. The intermediate insulating layer may include at least one intermediate inorganic layer and at least one intermediate organic layer. The circuit element may include a pixel-driving circuit included in each of pixels displaying the images and a sensor driving circuit included in each of sensors recognizing external information. The external information may be the biometric information. As an example, the sensor may be a fingerprint recognition sensor, a proximity sensor, an iris recognition sensor, or the like. In addition, the sensor may be an optical sensor that recognizes the biometric information in an optical manner. The circuit layer DP_CL may further include signal lines connected to the pixel-driving circuit and/or the sensor driving circuit.

The element layer DP_ED may include a light-emitting element included in each of the pixels and a light-sensing element included in each of the sensors. As an example, the light-sensing element may be a photodiode. The light-sensing element may be a sensor that senses a light reflected by a user's fingerprint or responds to the light. The circuit layer DP_CL and the element layer DP_ED will be described in detail later.

The thin film encapsulation layer TFE may encapsulate the element layer DP_ED. The thin film encapsulation layer TFE may include at least one organic layer and at least one inorganic layer. The inorganic layer may include an inorganic material, and may protect the element layer DP_ED from moisture and oxygen. The inorganic layer may include a silicon nitride layer, a silicon oxynitride layer, a silicon oxide layer, a titanium oxide layer, or an aluminum oxide layer, although it should not be particularly limited. The organic layer may include an organic material, and may protect the element layer DP_ED from a foreign substance such as dust particles. The thin film encapsulation layer TFE may include an inorganic layer, an organic layer, and an inorganic layer, which are sequentially stacked.

The input-sensing layer ISL may be located on the display panel DP. The input-sensing layer ISL may be located directly on the thin film encapsulation layer TFE. According to one or more embodiments, the input-sensing layer ISL may be formed on the display panel DP through a continuous process. That is, an adhesive member may not be located between the input-sensing layer ISL and the display panel DP.

The input-sensing layer ISL may sense the external input (e.g., a user's touch), may convert the external input to an input signal, and may apply the input signal to the display panel DP. The input-sensing layer ISL may include a plurality of input-sensing electrodes to sense the external input. The sensing electrodes may sense the external input by a mutual capacitance method or a self-capacitance method. The display panel DP may receive the input signal from the input-sensing layer ISL, and may generate an image corresponding to the input signal.

The anti-reflective layer ARL may be located on the input-sensing layer ISL, although the present disclosure should not be limited thereto or thereby. The input-sensing layer ISL and the anti-reflective layer ARL will be described in detail later.

The display device DD may further include an adhesive layer AL. The window WM may be attached to the input-sensing layer ISL by the adhesive layer AL. The adhesive layer AL may include an optically clear adhesive (OCA), an optically clear adhesive resin (OCR), or a pressure sensitive adhesive (PSA).

Referring to FIGS. 2 and 3, the housing EDC may be coupled to the window WM. The housing EDC may be coupled to the window WM to provide an inner space. The display module DM may be accommodated in the inner space. The housing EDC may include a material with a relatively high rigidity. For example, the housing EDC may include a glass, plastic, or metal material or a plurality of frames and/or plates of combinations thereof. The housing EDC may stably protect the components of the display device DD accommodated in the inner space from external impacts. In one or more embodiments, a battery module may be located between the display module DM and the housing EDC to supply a power source required for an overall operation of the display device DD.

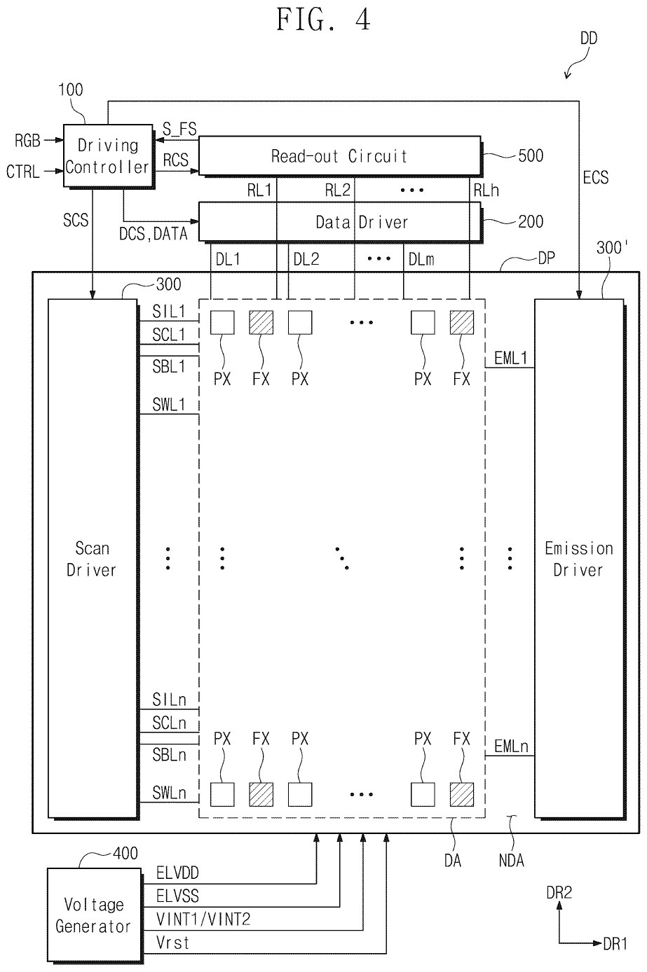

FIG. 4 is a block diagram of the display device DD according to one or more embodiments of the present disclosure.

Referring to FIG. 4, the display device DD may include the display panel DP, a driving controller 100, and a driving circuit. As an example, the driving circuit may include a data driver 200, a scan driver 300, an emission driver 300', a voltage generator 400, and a read-out circuit 500. According to one or more embodiments of the present disclosure, the voltage generator 400 and the read-out circuit 500 may be implemented in a single chip.

The driving controller 100 may receive an image signal RGB and control signals CTRL. The driving controller 100 may convert a data format of the image signal RGB to a data format appropriate to an interface between the data driver 200 and the driving controller 100 to generate an image data signal DATA. The driving controller 100 may generate a first control signal SCS, a second control signal ECS, a third control signal DCS, and a fourth control signal RCS.

The data driver 200 may receive the third control signal DCS and the image data signal DATA from the driving controller 100. The data driver 200 may convert the image data signal DATA to data signals and may output the data signals to a plurality of data lines DL1 to DLm described later. The data signals may be analog voltages corresponding to grayscale values of the image data signal DATA.

The scan driver 300 may receive the first control signal SCS from the driving controller 100. The scan driver 300 may output scan signals to scan lines in response to the first control signal SCS.

The voltage generator 400 may generate voltages required to operate the display panel DP. The voltage generator 400 may generate a first driving voltage ELVDD, a second driving voltage ELVSS, a first initialization voltage VINT1, and a second initialization voltage VINT2.

The display panel DP may include a plurality of pixels PX located in the display area DA, and a plurality of sensors FX located in the display area DA. As an example, each of the sensors FX may be located between two pixels PX adjacent to each other. The pixels PX and the sensors FX may be alternately arranged with each other in the first and second directions DR1 and DR2, although the present disclosure should not be limited thereto or thereby. That is, two or more pixels PX may be located between two sensors FX adjacent to each other in the first direction DR1 among the sensors FX, or two or more pixels PX may be located between two sensors FX adjacent to each other in the second direction DR2 among the sensors FX.

The display panel DP may further include initialization scan lines SIL1 to SILn, compensation scan lines SCL1 to SCLn, write scan lines SWL1 to SWLn, black scan lines SBL1 to SBLn, emission control lines EML1 to EMLn, the data lines DL1 to DLm, and read-out lines RL1 to RLh. The initialization scan lines SIL1 to SILn, the compensation scan lines SCL1 to SCLn, the write scan lines SWL1 to SWLn, the black scan lines SBL1 to SBLn, and the emission control lines EML1 to EMLn may extend in the second direction DR2. The initialization scan lines SIL1 to SILn, the compensation scan lines SCL1 to SCLn, the write scan lines SWL1 to SWLn, the black scan lines SBL1 to SBLn, and the emission control lines EML1 to EMLn may be arranged in the first direction DR1, and may be spaced apart from each other. The data lines DL1 to DLm and the read-out lines RL1 to RLh may extend in the first direction DR1, and may be arranged spaced apart from each other in the second direction DR2.

The pixels PX may be electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and the data lines DL1 to DLm. As an example, each of the pixels PX may be electrically connected to four scan lines. However, the number of the scan lines connected to each of the pixels PX should not be limited to four and may be changed.

The sensors FX may be electrically connected to the write scan lines SWL1 to SWLn and the read-out lines RL1 to RLh. Each of the sensors FX may be electrically connected to one scan line, although the present disclosure should not be limited thereto or thereby. The number of the scan lines connected to each of the sensors FX may vary. As an example, the number of the read-out lines RL1 to RLh may correspond to about a half (½) of the number of the data lines DL1 to DLm, although the present disclosure should not be limited thereto or thereby. Alternatively, the number of the read-out lines RL1 to RLh may correspond to about a fourth (¼) or about an eighth (⅛) of the number of the data lines DL1 to DLm.

The scan driver 300 may be located in the non-display area NDA of the display panel DP. The scan driver 300 may receive the first control signal SCS from the driving controller 100. Responsive to the first control signal SCS, the scan driver 300 may output initialization scan signals to the initialization scan lines SIL1 to SILn, and may output compensation scan signals to the compensation scan lines SCL1 to SCLn. In addition, responsive to the first control signal SCS, the scan driver 300 may output write scan signals to the write scan lines SWL1 to SWLn, and may output black scan signals to the black scan lines SBL1 to SBLn. Alternatively, the scan driver 300 may include first and second scan drivers. The first scan driver may output the initialization scan signals and the compensation scan signals, and the second scan driver may output the write scan signals and the black scan signals.

The emission driver 300′ may be located in the non-display area NDA of the display panel DP. The emission driver 300′ may receive the second control signal ECS from the driving controller 100. The emission driver 300′ may output emission control signals to the emission control lines EML1 to EMLn in response to the second control signal ECS. According to one or more embodiments, alternatively, the scan driver 300 may be connected to the emission control lines EML1 to EMLn. In this case, the emission driver 300′ may be omitted, and the scan driver 300 may output the emission control signals to the emission control lines EML1 to EMLn.

The read-out circuit 500 may receive the fourth control signal RCS from the driving controller 100. The read-out circuit 500 may receive sensing signals from the read-out lines RL1 to RLh in response to the fourth control signal RCS. The read-out circuit 500 may process the sensing signals received from the read-out lines RL1 to RLh, and may provide the processed sensing signals S_FS to the driving controller 100. The driving controller 100 may recognize the biometric information based on the sensing signals S_FS.

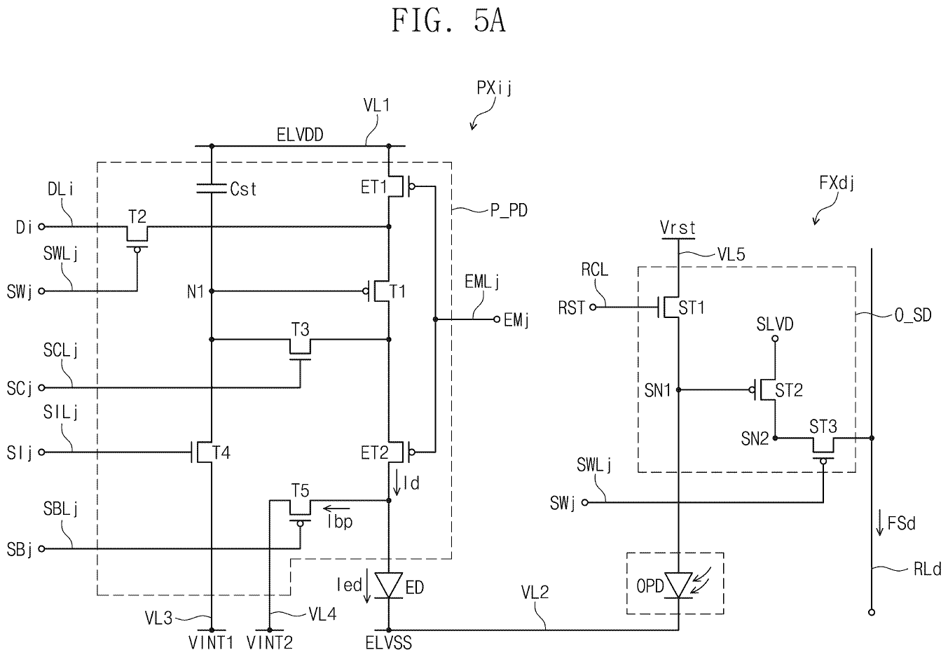

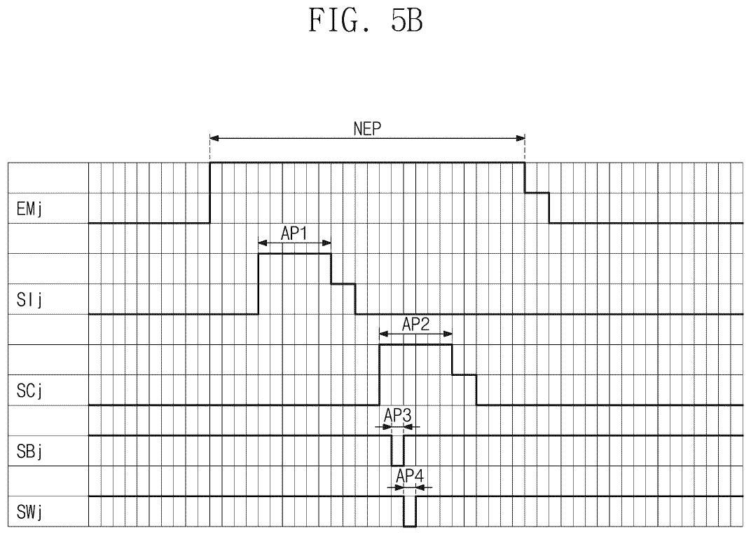

FIG. 5A is a circuit diagram of a pixel PXij and a sensor FXdj according to one or more embodiments of the present disclosure, and FIG. 5B is a waveform diagram illustrating an operation of the pixel PXij and the sensor FXdj shown in FIG. 5A.

FIG. 5A shows an equivalent circuit diagram of one pixel PXij among the pixels PX shown in FIG. 4. Because the pixels PX have substantially the same circuit configuration, the circuit configuration of one pixel PXij will be described in detail, and descriptions of the other pixels will be omitted. In addition, FIG. 5A shows an equivalent circuit diagram of one sensor FXdj of the sensors FX shown in FIG. 4. Because the sensors FX have substantially the same circuit configuration, the circuit configuration of one sensor FXdj will be described in detail, and descriptions of the other sensors will be omitted.

Referring to FIGS. 4 and 5A, the pixel PXij may be connected to an i-th data line DLi among the data lines DL1 to DLm, a j-th initialization scan line SILj among the initialization scan lines SIL1 to SILn, a j-th compensation scan line SCLj among the compensation scan lines SCL1 to SCLn, a j-th write scan line SWLj among the write scan lines SWL1 to SWLn, a j-th black scan line SBLj among the black scan lines SBL1 to SBLn, and a j-th emission control line EMLj among the emission control lines EML1 to EMLn.

The pixel PXij may include a light-emitting element ED and a pixel-driving circuit P_PD. The light-emitting element ED may be a light-emitting diode. As an example, the light-emitting element ED may be an organic light-emitting diode including an organic light-emitting layer.

The pixel-driving circuit P_PD may include first, second, third, fourth, and fifth transistors T1, T2, T3, T4, and T5, first and second emission control transistors ET1 and ET2, and one capacitor Cst. At least one of the first to fifth transistors T1 to T5 and/or the first and/or second emission control transistors ET1 and ET2 may be a transistor including a low-temperature polycrystalline silicon (LTPS) semiconductor layer.

At least one of the first to fifth transistors T1 to T5 and/or the first and/or second emission control transistors ET1 and ET2 may be a transistor including an oxide semiconductor layer. As an example, the third and fourth transistors T3 and T4 may be the oxide semiconductor transistor, and the first, second, and fifth transistors T1, T2, and T5 and the first and second emission control transistors ET1 and ET2 may be a silicon transistor.

Some transistors of the first to fifth transistors T1 to T5 and the first and second emission control transistors ET1 and ET2 may be a P-type transistor, and the other transistors may be an N-type transistor.

As an example, each of the first, second, and fifth transistors T1, T2, and T5 and the first and second emission control transistors ET1 and ET2 may be a PMOS transistor, and each of the third and fourth transistors T3 and T4 may be an NMOS transistor.

Hereinafter, a source, a drain, and a gate of the first, second, and fifth transistors T1, T2, and T5 and the first and second emission control transistors ET1 and ET2 will be described based on the PMOS transistor, and a source, a drain, and a gate of the third and fourth transistors T3 and T4 will be described based on the NMOS transistor.

The circuit configuration of the pixel-driving circuit P_PD according to the present disclosure should not be limited to the one or more embodiments corresponding to FIG. 5A. The pixel-driving circuit P_PD shown in FIG. 5A is merely an example, and the circuit configuration of the pixel-driving circuit P_PD may be changed. As an example, all the first to fifth transistors T1 to T5 and the first and second emission control transistors ET1 and ET2 may be the P-type transistor or the N-type transistor.

The j-th initialization scan line SILj, the j-th compensation scan line SCLj, the j-th write scan line SWLj, the j-th black scan line SBLj, and the j-th emission control line EMLj may transmit a j-th initialization scan signal SIj, a j-th compensation scan signal SCj, a j-th write scan signal SWj, a j-th black scan signal SBj, and a j-th emission control signal EMj to the pixel PXij, respectively. The i-th data line DLi may transmit an i-th data signal Di to the pixel PXij. The i-th data signal Di may have a voltage level corresponding to the image signal RGB (refer to FIG. 4) input to the display device DD (refer to FIG. 4).

First and second driving voltage lines VL1 and VL2 may respectively transmit the first driving voltage ELVDD and the second driving voltage ELVSS to the pixel PXij. In addition, first and second initialization voltage lines VL3 and VL4 may respectively transmit the first initialization voltage VINT1 and the second initialization voltage VINT2 to the pixel PXij.

The first transistor T1 may be connected between the first driving voltage line VL1, to which the first driving voltage ELVDD is applied, and the light-emitting element ED. The first transistor T1 may include the source connected to the first driving voltage line VL1 through the first emission control transistor ET1, the drain connected to a first electrode (or an anode) of the light-emitting element ED through the second emission control transistor ET2, and the gate connected to one end of the capacitor Cst (e.g., a first node N1). The first transistor T1 may receive the i-th data signal Di via the i-th data line DLi according to a switching operation of the second transistor T2, and may supply a driving current Id to the light-emitting element ED.

The second transistor T2 may be connected between the data line DLi and the source of the first transistor T1. The second transistor T2 may include the source connected to the i-th data line DLi, the drain connected to the source of the first transistor T1, and the gate connected to the j-th write scan line SWLj. The second transistor T2 may be turned on in response to the write scan signal SWj applied through the j-th write scan line SWLj, and may transmit the i-th data signal Di provided from the i-th data line DLi to the source of the first transistor T1.

The third transistor T3 may be connected between the drain of the first transistor T1 and the first node N1. The third transistor T3 may include the source connected to the gate of the first transistor T1, the drain connected to the drain of the first transistor T1, and the gate connected to the j-th compensation scan line SCLj. The third transistor T3 may be turned on in response to the j-th compensation scan signal SCj applied through the j-th compensation scan line SCLj and may connect the drain and the gate of the first transistor T1, and thus, the first transistor T1 may be connected in a diode configuration.

The fourth transistor T4 may be connected between the first initialization voltage line VL3 to which the first initialization voltage VINT1 is applied and the first node N1. The fourth transistor T4 may include the source connected to the first initialization voltage line VL3 to which the first initialization voltage VINT1 is applied, the drain connected to the first node N1, and the gate connected to the j-th initialization scan line SILj. The fourth transistor T4 may be turned on in response to the j-th initialization scan signal SIj applied the through the j-th initialization scan line SILj. The turned-on fourth transistor T4 may supply the first initialization voltage VINT1 to the first node N1 to initialize an electric potential of the gate of the first transistor T1 (e.g., an electric potential of the first node N1).

The fifth transistor T5 may include the drain connected to the second initialization voltage line VL4 to which the second initialization voltage VINT2 is applied, the source connected to the drain of the second emission control transistor ET2, and the gate connected to the black scan line SBLj. The second initialization voltage VINT2 may have a voltage level that is lower than or equal to that of the first initialization voltage VINT1.

The first emission control transistor ET1 may include the source connected to the first driving voltage line VL1, the drain connected to the source of the first transistor T1, and the gate connected to the j-th emission control line EMLj. The second emission control transistor ET2 may include the source connected to the drain of the first transistor T1, the drain connected to the first electrode of the light-emitting element ED, and the gate connected to the j-th emission control line EMLj. The first and the second emission control transistors ET1 and ET2 may be substantially concurrently or substantially simultaneously turned on in response to the j-th emission control signal EMj applied through the j-th emission control line EMLj. The first driving voltage ELVDD provided through the turned-on first emission control transistor ET1 may be compensated for through the diode-connected first transistor T1, and then may be supplied to the light-emitting element ED.

As described above, the one end of the capacitor Cst may be connected to the gate of the first transistor T1, and the other end of the capacitor Cst may be connected to the first driving voltage line VL1. A second electrode (or a cathode) of the light-emitting element ED may be connected to the second driving voltage line VL2 for transmitting the second driving voltage ELVSS. The second driving voltage ELVSS may have a voltage level lower than that of the first driving voltage ELVDD. As an example, the second driving voltage ELVSS may have a voltage level lower than that of the first and second initialization voltages VINT1 and VINT2.

Referring to FIGS. 5A and 5B, the j-th emission control signal EMj may have a high level during a non-light-emitting period NEP. The j-th initialization scan signal SIj may be activated within the non-light-emitting period NEP. When the j-th initialization scan signal SIj having the high level is provided through the j-th initialization scan line SILj during an activation period AP1 (hereinafter, referred to as a first activation period) of the j-th initialization scan signal SIj, the fourth transistor T4 may be turned on in response to the j-th initialization scan signal SIj having the high level. The first initialization voltage VINT1 may be applied to the gate of the first transistor T1 through the turned-on fourth transistor T4, and the first node N1 may be initialized to the first initialization voltage VINT1. Accordingly, the first activation period AP1 may be defined as an initialization period of the pixel PXij.

Then, when the j-th compensation scan signal SCj is activated and the j-th compensation scan signal SCj having the high level is provided through the j-th compensation scan line SCLj during an activation period AP2 (hereinafter, referred to as a second activation period) of the j-th compensation scan signal SCj, the third transistor T3 may be turned on. The first transistor T1 may be connected in a diode configuration by the turned-on third transistor T3 and may be forward biased. The first activation period AP1 may not overlap the second activation period AP2.

The j-th write scan signal SWj may be activated within the second activation period AP2. The j-th write scan signal SWj may have a low level during an activation period AP4 (hereinafter, referred to as a fourth activation period). The second transistor T2 may be turned on in response to the j-th write scan signal SWj having the low level during the fourth activation period AP4. Then, a compensation voltage “Di-Vth”, which is reduced by a threshold voltage Vth of the first transistor T1 from the i-th data signal Di provided through the i-th data line DLi, may be applied to the gate of the first transistor T1. That is, an electric potential of the gate of the first transistor T1 may be the compensation voltage “Di-Vth”. The fourth activation period AP4 may overlap the second activation period AP2. A duration of the second activation period AP2 may be longer than a duration of the fourth activation period AP4.

The first driving voltage ELVDD and the compensation voltage “Di-Vth” may be respectively applied to opposite ends of the capacitor Cst, and the capacitor Cst may be charged with electric charges corresponding to a difference in voltage between the opposite ends of the capacitor Cst. A high level period of the j-th compensation scan signal SCj may be referred to as a compensation period of the pixel PXij.

The j-th black scan signal SBj may be activated within the second activation period AP2 of the j-th compensation scan signal SCj. The j-th black scan signal SBj may have the low level during an activation period AP3 (hereinafter, referred to as a third activation period). During the third activation period AP3, the fifth transistor T5 may be turned on in response to the j-th black scan signal SBj having the low level applied through the j-th black scan line SBLj. A portion of the driving current Id may be bypassed as a bypass current Ibp via the fifth transistor T5. The third activation period AP3 may overlap the second activation period AP2. The duration of the second activation period AP2 may be longer than a duration of the third activation period AP3. The third activation period AP3 may precede the fourth activation period AP4, and might not overlap the fourth activation period AP4.

In a case where the pixel PXij displays a black image, if the light-emitting element ED emits light even when a minimum driving current of the first transistor T1 flows as the driving current Id, the pixel PXij may not properly display the black image. Therefore, in the pixel PXij according to one or more embodiments, the fifth transistor T5 may divert part of the minimum driving current of the first transistor T1 as the bypass current Ibp along a path different from the current path to the light-emitting element ED. In this case, the minimum driving current of the first transistor T1 may refer to a current flowing through the first transistor T1 under a condition that a gate-source voltage Vgs of the first transistor T1 is lower than the threshold voltage Vth, and the first transistor T1 is turned off. The minimum driving current flowing through the first transistor T1 under the condition that the first transistor T1 is turned off (e.g., a current of less than about 10 pA) is transmitted to the light-emitting element ED, and an image with a black grayscale may be displayed. In the case where the pixel PXij displays the black image, an influence of the bypass current Ibp on the minimum driving current is relatively large, although, in the case where images are display, such as a normal image or a white image, the influence of the bypass current Ibp on the driving current Id may be considered negligible. Accordingly, when the black image is displayed, a current (e.g., a light-emitting current Ied), which is reduced by an amount of the bypass current Ibp flowing out from the driving current Id through the fifth transistor T5, may be provided to the light-emitting element ED, enabling a more accurate representation of the black image. Thus, the pixel PXij may display an accurate black grayscale image utilizing the fifth transistor T5, and as a result, a contrast ratio may be improved.

Then, a level of the j-th emission control signal EMj provided from the j-th emission control line EMLj may be changed to the low level from the high level. The first and second emission control transistors ET1 and ET2 may be turned on in response to the j-th emission control signal EMj having the low level. As a result, the driving current Id may be generated due to a difference in voltage between the voltage of the gate of the first transistor T1 and the first driving voltage ELVDD, the driving current Id may be supplied to the light-emitting element ED via the second emission control transistor ET2, and thus, the light-emitting current Ied may flow through the light-emitting element ED.

Referring to FIG. 5A again, the sensor FXdj may be connected to a d-th read-out line RLd among the read-out lines RL1 to RLh, the j-th write scan line SWLj, and a reset control line RCL.

The sensor FXdj may include a light-sensing element OPD and a sensor driving circuit O_SD. As an example, the light-sensing element OPD may be an organic photodiode including an organic material as a photoelectric conversion layer. FIG. 5A shows a structure in which the sensor FXdj includes one light-sensing element as a representative example, although the present disclosure should not be limited thereto or thereby. As an example, the sensor FXdj may include a plurality of light-sensing elements OPD connected to each other in parallel.

An anode electrode of the light-sensing element OPD may be connected to a first sensing node SN1, and a cathode electrode of the light-sensing element OPD may be connected to the second driving voltage line VL2 transmitting the second driving voltage ELVSS. The cathode electrode of the light-sensing element OPD may be electrically connected to the cathode electrode of the light-emitting element ED. As an example, the cathode electrode of the light-sensing element OPD may be formed integrally with the cathode electrode of the light-emitting element ED to form a common cathode electrode.

The sensor driving circuit O_SD may include three transistors ST1, ST2, and ST3. The three transistors ST1, ST2, and ST3 may be a reset transistor ST1, an amplification transistor ST2, and an output transistor ST3, respectively. At least one of the reset transistor ST1, the amplification transistor ST2, or the output transistor ST3 may be an oxide semiconductor transistor. As an example, the reset transistor ST1 may be the oxide semiconductor transistor, and the amplification transistor ST2 and the output transistor ST3 may be the LTPS transistor, although the present disclosure should not be limited thereto or thereby. According to one or more embodiments, at least the reset transistor ST1 and the output transistor ST3 may be the oxide semiconductor transistor, and the amplification transistor ST2 may be the LTPS transistor.

In addition, some of the reset transistor ST1, the amplification transistor ST2, and the output transistor ST3 may be the P-type transistor, and the other transistors may be the N-type transistor. As an example, the amplification transistor ST2 and the output transistor ST3 may be the PMOS transistor, and the reset transistor ST1 may be the NMOS transistor, although the present disclosure should not be limited thereto or thereby. According to one or more embodiments, the reset transistor ST1, the amplification transistor ST2, and the output transistor ST3 may all be the N-type transistor or may all be the P-type transistor. Hereinafter, a source, a drain, and a gate of the amplification transistor ST2 and the output transistor ST3 will be described based on the PMOS transistor, and the source, drain, and gate of the reset transistor ST1 will be described based on the NMOS transistor.

One or more transistors (e.g., the reset transistor ST1) among the reset transistor ST1, the amplification transistor ST2, and the output transistor ST3 may be the same type of transistor as the third and fourth transistors T3 and T4 of the pixel PXij. The amplification transistor ST2 and the output transistor ST3 may be the same type of transistor as the first, second, and fifth transistors T1, T2, and T5 and the first and second emission control transistors ET1 and ET2 of the pixel PXij.

The circuit configuration of the sensor driving circuit O_SD should not be limited to that shown in FIG. 5A. The sensor driving circuit O_SD shown in FIG. 5A is merely an example, and the circuit configuration of the sensor driving circuit O_SD may be modified in various ways.

The reset transistor ST1 may include the source for receiving a reset voltage Vrst, the drain connected to the first sensing node SN1, and the gate for receiving a reset control signal RST. The reset transistor ST1 may reset an electric potential of the first sensing node SN1 to the reset control signal RST in response to the reset control signal RST. The reset control signal RST may be a signal provided through the reset control line RCL, although the present disclosure should not be limited thereto or thereby. Alternatively, the reset control signal RST may be the j-th compensation scan signal SCj provided through the j-th compensation scan line SCLj. That is, the reset transistor ST1 may receive the j-th compensation scan signal SCj provided through the j-th compensation scan line SCLj as the reset control signal RST. As an example, the reset voltage Vrst may have a voltage level that is lower than that of the second driving voltage ELVSS at least during an activation period of the reset control signal RST. The reset voltage Vrst may be a DC voltage maintained at a voltage level lower than that of the second driving voltage ELVSS.

The amplification transistor ST2 may include the source for receiving a sensing-driving voltage SLVD, the drain connected to a second sensing node SN2, and the gate connected to the first sensing node SN1. The amplification transistor ST2 may be turned on according to the electric potential of the first sensing node SN1, and may apply the sensing-driving voltage SLVD to the second sensing node SN2. As an example, the sensing-driving voltage SLVD may be one of the first driving voltage ELVDD or the first or second initialization voltages VINT1 or VINT2. When the sensing-driving voltage SLVD is the first driving voltage ELVDD, the source of the amplification transistor ST2 may be electrically connected to the first driving voltage line VL1. When the sensing-driving voltage SLVD is the first initialization voltage VINT1, the source of the amplification transistor ST2 may be electrically connected to the first initialization voltage line VL3, and when the sensing-driving voltage SLVD is the second initialization voltage VINT2, the source of the amplification transistor ST2 may be electrically connected to the second initialization voltage line VL4.

The output transistor ST3 may include the source connected to the second sensing node SN2, the drain connected to the d-th read-out line RLd, and the gate receiving an output control signal. The output transistor ST3 may apply a sensing signal FSd to the d-th read-out line RLd in response to the output control signal. The output control signal may be the j-th write scan signal SWj provided through the j-th write scan line SWLj. That is, the output transistor ST3 may receive the j-th write scan signal SWj provided through the j-th write scan line SWLj as the output control signal.

The light-sensing element OPD of the sensor FXdj may be exposed to the light during the light emission period of the light-emitting element ED. The light may be the light emitted from the light-emitting element ED.

When the user's finger US_F (refer to FIG. 1A) touches the display surface FS (refer to FIG. 1A), the light-sensing element OPD may generate photo-charges corresponding to the light reflected by ridges of the user's fingerprint or valleys between the ridges of the user's fingerprint, and the generated photo-charges may be accumulated in the first sensing node SN1. The amplification transistor ST2 may be a source follower amplifier that generates a source-drain current in proportion to an amount of charge of the first sensing node SN1 input to the gate.

During the fourth activation period AP4 (refer to FIG. 5B), the j-th write scan signal SWj having the low level may be applied to the output transistor ST3 via the j-th write scan line SWLj. When the output transistor ST3 is turned on in response to the j-th write scan signal SWj having the low level, the sensing signal FSd corresponding to a current flowing through the amplification transistor ST2 may be output to the d-th read-out line RLd.

Then, when the reset control signal RST having the high level is provided through the reset control line RCL during a reset period, the reset transistor ST1 may be turned on. The reset period may be defined as an activation period of the reset control line RCL (e.g., a high level period). Alternatively, when the reset transistor ST1 is the PMOS transistor, the reset control signal RST having the low level may be applied to the reset control line RCL during the reset period. During the reset period, the first sensing node SN1 may be reset to an electric potential corresponding to the reset voltage Vrst. As an example, the reset voltage Vrst may have a voltage level lower than that of the second driving voltage ELVSS.

Then, when the reset period is finished, the light-sensing element OPD may generate photo-charges corresponding to the light provided thereto, and the generated photo-charges may be accumulated in the first sensing node SN1.

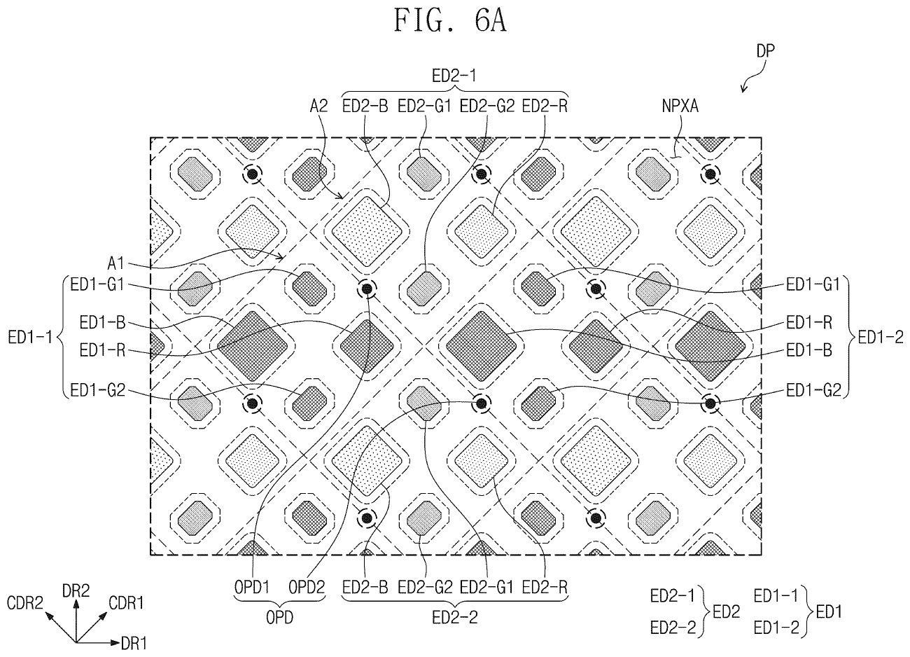

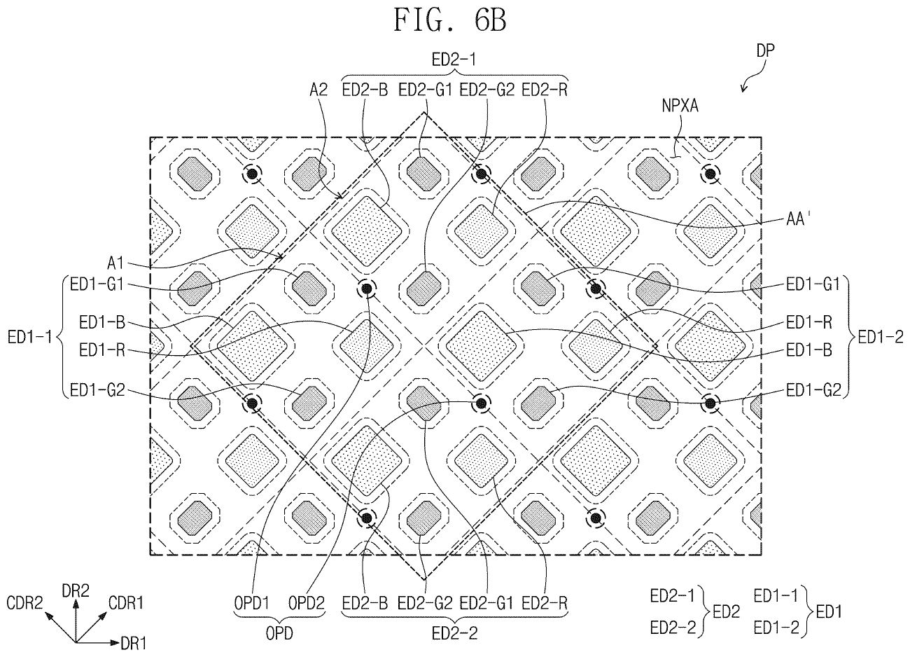

FIG. 6A is a plan view of a portion of the display panel DP in the first operation mode (hereinafter, referred to as the first mode) according to one or more embodiments of the present disclosure, and FIG. 6B is a plan view of a portion of the display panel DP in the second operation mode (hereinafter, referred to as the second mode) according to one or more embodiments of the present disclosure.

Referring to FIGS. 6A and 6B, the light-emitting elements located in different areas of the display panel DP are shown. A first area A1 and a second area A2 may be provided in plural in the display area DA (refer to FIG. 2) of the display panel DP. That is, the first areas A1 and the second areas A2 may be defined in the base layer BL (refer to FIG. 3) included in the display panel DP.

According to the present disclosure, the first areas A1 may be arranged in the first direction DR1 and the second direction DR2. The second areas A2 may be arranged in the first direction DR1 and the second direction DR2. The first areas A1 and the second areas A2 may be arranged in a first diagonal direction CDR1 and a second diagonal direction CDR2, which cross the first direction DR1 and the second direction DR2. That is, the first areas A1 and the second areas A2 may be alternately arranged with each other in the first diagonal direction CDR1 and in the second diagonal direction CDR2. Each of the first areas A1 and each of the second areas A2 may have a lozenge shape (e.g., a rhombus shape) when viewed in the plane.

According to one or more embodiments, four distinct second areas A2 may be arranged adjacent to one first area A1 in the first diagonal direction CDR1 and in the second diagonal direction CDR2, and four distinct first areas A1 may be arranged adjacent to one second area A2 in the first diagonal direction CDR1 and in the second diagonal direction CDR2. Accordingly, a different area may be placed adjacent to each one side defining the lozenge shape.

Each of the first areas A1 and each of the second areas A2 may include a light-emitting area and a peripheral area. As an example, a first group of light-emitting elements ED1 may be located in the light-emitting area of the first areas A1, and a second group of light-emitting elements ED2 may be located in the light-emitting area of the second areas A2. Accordingly, the first group of light-emitting elements ED1 may be spaced apart from the second group of light-emitting elements ED2 in the first diagonal direction CDR1 and the second diagonal direction CDR2. An area surrounding the first group of light-emitting elements ED1 and the second group of light-emitting elements ED2 may be defined as the peripheral area NPXA.

As described above, the display device DD (refer to FIG. 3) may operate in two modes. As shown in FIG. 6A, during the first mode, the first group of light-emitting elements ED1 included in the first area A1 of the display panel DP may be deactivated, and the second group of light-emitting elements ED2 included in the second area A2 of the display panel DP may be activated. As shown in FIG. 6B, during the second mode, the first group of light-emitting elements ED1 located in the first area A1 of the display panel DP and the second group of light-emitting elements ED2 located in the second area A2 of the display panel DP may be activated. Accordingly, a size of the light-emitting areas activated in the first mode may be relatively smaller compared to the second mode, and thus, images with lower pixel counts may be provided to the user. That is, because the first mode is the private mode, when the display device DD (refer to FIG. 3) operates in the first mode, the display area DA (refer to FIG. 2) may not be visible to individuals near the display device DD (refer to FIG. 3) but may be visible only to the user. As a result, a possibility of the leakage of personal information may be reduced or prevented.

According to one or more embodiments of the present disclosure, the first group of light-emitting elements ED1 may include light-emitting elements with a relatively wide viewing angle, and the second group of light-emitting elements ED2 may include light-emitting elements with a relatively narrow viewing angle.

Referring to FIGS. 6A and 6B, the first group of light-emitting elements ED1 may include a first light-emitting element ED1-B emitting a first color light, a second light-emitting element ED1-R spaced apart from the first light-emitting element ED1-B in the first direction DR1 and emitting a second color light, a third-first light-emitting element ED1-G1 emitting a third color light, and a third-second light-emitting element ED1-G2 emitting the third color light and spaced apart from the third-first light-emitting element ED1-G1 in the second direction DR2.

The third-first light-emitting element ED1-G1 may be spaced apart from the first light-emitting element ED1-B in the first diagonal direction CDR1, and the third-second light-emitting element ED1-G2 may be spaced apart from the second light-emitting element ED1-R in the first diagonal direction CDR1.

The first color light may be a blue light, the second color light may be a red light, and the third color light may be a green light. According to one or more embodiments, each of the first group of light-emitting elements ED1 and the second group of light-emitting elements ED2 may include one red light-emitting element, one blue light-emitting element, and two green lights emitting elements. However, this is merely an example, and the number of the light-emitting elements may be different from the number mentioned above.

As an example, the second light-emitting element ED1-R may have a size that is greater than the third-first light-emitting element ED1-G1 and the third-second light-emitting element ED1-G2. In addition, the first light-emitting element ED1-B may have a size that is greater than or equal to the second light-emitting element ED1-R. The size of each of the light-emitting elements ED1-B, ED1-R, ED1-G1, and ED1-G2 should not be limited thereto or thereby, and may be changed in various ways. For instance, according to one or more embodiments, the light-emitting elements ED1-B, ED1-R, ED1-G1, and ED1-G2 may have substantially the same size.

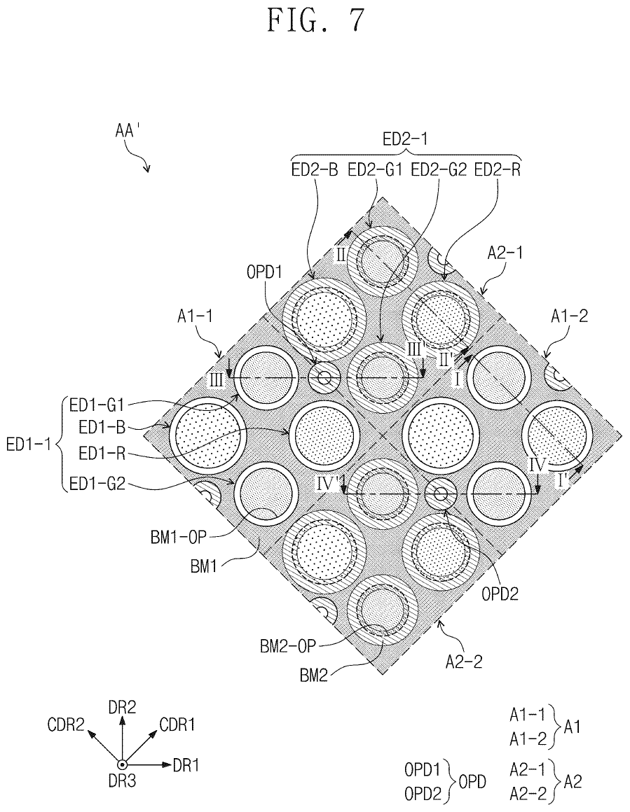

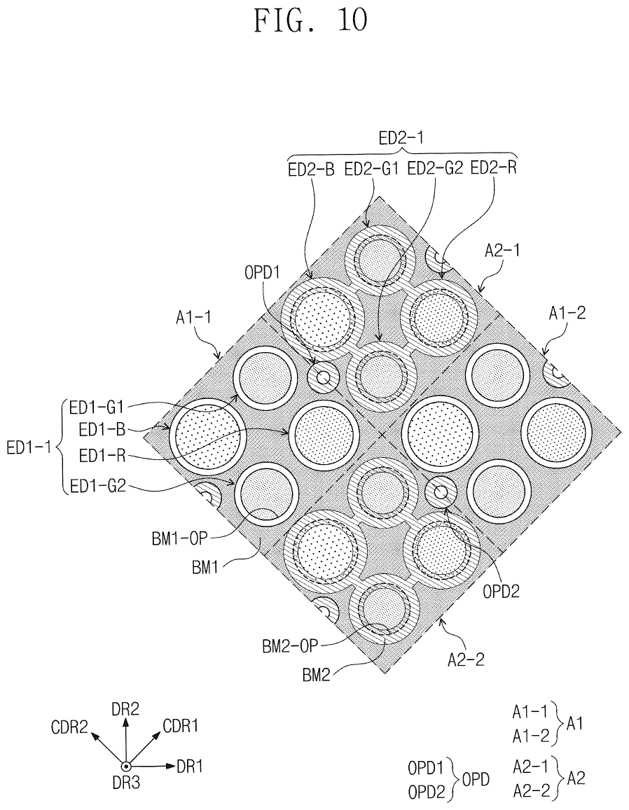

Each of the light-emitting elements ED1-B, ED1-R, ED1-G1, and ED1-G2 may have a polygonal shape (for example, one of a lozenge shape, a square shape, a rectangular shape, a hexagonal shape, or an octagonal shape), a circular shape, or an oval shape. The third-first light-emitting element ED1-G1 and the third-second light-emitting element ED1-G2 may have a shape that is different from that of the first light-emitting element ED1-B and the second light-emitting element ED1-R. As an example, each of the first light-emitting element ED1-B and the second light-emitting element ED1-R may have a lozenge shape with rounded corners, and each of the third-first light-emitting element ED1-G1 and the third-second light-emitting element ED1-G2 may have an octagonal shape. However, the present disclosure should not be limited thereto or thereby, and each of light-emitting elements ED1-B, ED1-R, ED1-G1, and ED1-G2 may have a circular shape as the light-emitting elements ED1-B, ED1-R, ED1-G1, and ED1-G2 described later with reference to FIGS. 7 and 10.

The second group of light-emitting elements ED2 may include a first light-emitting element ED2-B emitting the first color light, a second light-emitting element ED2-R spaced apart from the first light-emitting element ED2-B in the first direction DR1 and emitting the second color light, a third-first light-emitting element ED2-G1 emitting the third color light, and a third-second light-emitting element ED2-G2 emitting the third color light and spaced apart from the third-first light-emitting element ED2-G1 in the second direction DR2. The descriptions on the first group of light-emitting elements ED1 may be generally equally applied to the second group of light-emitting element ED2.

According to one or more embodiments of the present disclosure, the first group of light-emitting elements ED1 may include a first-first group of light-emitting elements ED1-1 and a first-second group of light-emitting elements ED1-2, which are arranged in the first direction DR1, and the second group of light-emitting elements ED2 may include a second-first group of light-emitting elements ED2-1 and a second-second group of light-emitting elements ED2-2, which are arranged in the second direction DR2.

As shown in FIGS. 6A and 6B, the light-sensing element OPD may be located between the first group of light-emitting elements ED1 and the second group of light-emitting elements ED2. The light-sensing element OPD may be provided in plural, and the light-sensing elements OPD may include, for example, a first light-sensing element OPD1 and a second light-sensing element OPD2.

The first light-sensing element OPD1 and the second light-sensing element OPD2 may be located at the same layer, and a cross-section of the first light-sensing element OPD1 and the second light-sensing element OPD2 will be described in detail later. The first light-sensing element OPD1 may be located between the first-first group of light-emitting elements ED1-1 and the second-first group of light-emitting elements ED2-1, and the second light-sensing element OPD2 may be located between the first-second group of light-emitting elements ED1-2 and the second-second group of light-emitting elements ED2-2.

According to one or more embodiments of the present disclosure, the first light-sensing element OPD1 may be located between the third-first light-emitting element ED1-G1 of the first group of light-emitting elements ED1 and the third-second light-emitting element ED2-G2 of the second group of light-emitting elements ED2 in the first direction DR1. The first light-sensing element OPD1 may be located between the second light-emitting element ED1-R of the first group of light-emitting elements ED1 and the first light-emitting element ED2-B of the second group of light-emitting elements ED2 in the second direction DR2.

As an example, each of the light-sensing elements OPD may have the same shape as, or a different shape from, each of the light-emitting elements ED1-B, ED1-R, ED1-G1, and ED1-G2. As shown in FIGS. 6A and 6B, each of the light-sensing elements OPD may have a circular shape. However, each of the light-sensing elements OPD may have a polygonal shape (for example, a lozenge shape, a square shape, a rectangular shape, a hexagonal shape, or an octagonal shape) or an oval shape.

Each of the light-sensing elements OPD may have a size that is smaller than or equal to the third-first light-emitting element ED1-G1 and the third-second light-emitting element ED1-G2. However, the size of each of the light-sensing elements OPD should not be limited thereto or thereby and may be changed in various ways.

As shown in FIG. 6B, a portion AA′ with a lozenge shape may include the first-first group of light-emitting elements ED1-1, the first-second group of light-emitting elements ED1-2, the second-first group of light-emitting elements ED2-1, and the second-second group of light-emitting elements ED2-2.

FIG. 7 is an enlarged plan view of a portion AA′ of a display panel DP in a second operation mode according to one or more embodiments of the present disclosure. That is, FIG. 7 is an enlarged plan view of the portion AA′ with the lozenge shape of FIG. 6B. The shape of the light-emitting elements in FIG. 7 is depicted as a circular shape for the convenience of explanation, although the shape of the light-emitting elements in FIG. 7 may be the same as the light-emitting elements of FIG. 6B. In addition, descriptions of the same elements as those described with reference to FIGS. 6A and 6B will be omitted.

The portion AA′ may include a first area A1 and a second area A2. The first area A1 may include a first-first area A1-1 in which a first-first group of light-emitting elements ED1-1 is located and a first-second area A1-2 in which a first-second group of light-emitting elements ED1-2 is located. The second area A2 may include a second-first area A2-1 in which a second-first group of light-emitting elements ED2-1 is located and a second-second area A2-2 in which a second-second group of light-emitting elements ED2-2 is located.

Referring to FIGS. 6B and 7, an opening BM1-OP corresponding to a first group of light-emitting elements ED1, to a second group of light-emitting elements ED2, and to light-sensing elements OPD1 and OPD2 may be defined through a first light-blocking layer BM1. In addition, a second light-blocking layer BM2 may not overlap the first area A1 and may overlap the second area A2. Further, an opening BM2-OP corresponding to the second group of light-emitting elements ED2 of the second area A2 may be defined through the second light-blocking layer BM2. That is, the opening BM2-OP of the second light-blocking layer BM2 may correspond to the opening BM1-OP of the first light-blocking layer BM1 that is formed in the second group of light-emitting elements ED2.

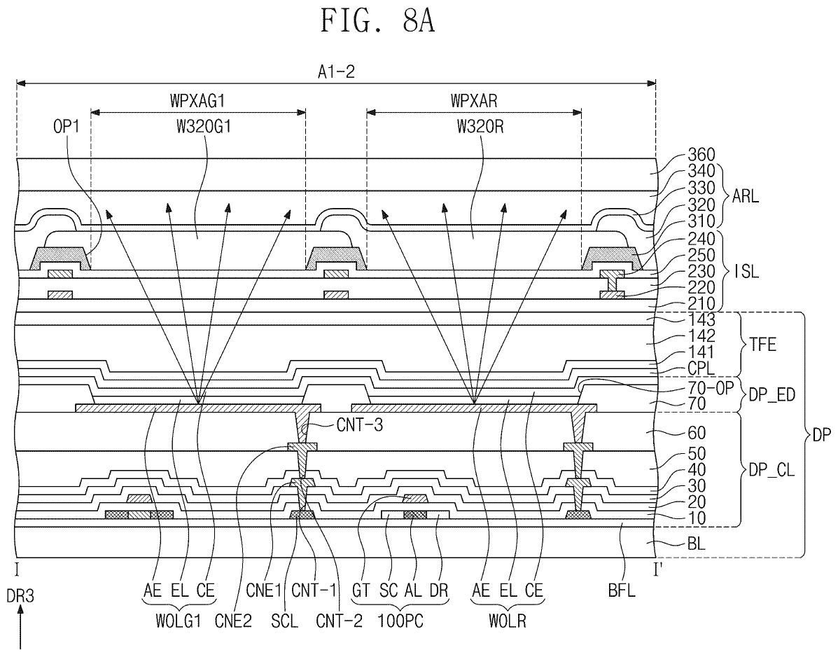

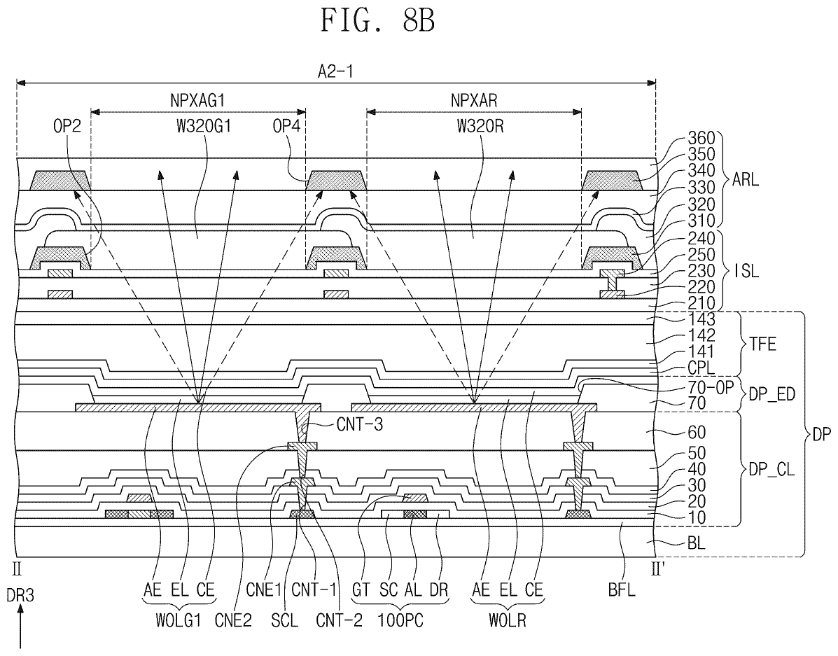

FIG. 8A is a cross-sectional view taken along the line I-I′ of FIG. 7, and FIG. 8B is a cross-sectional view taken along the line II-II′ of FIG. 7. FIG. 8A is a cross-sectional view showing the first area A1 of the display device DD (e.g., the first-second area A1-2 of the first area A1). FIG. 8B is a cross-sectional view showing the second area A2 of the display device DD (e.g., the second-first area A2-1 of the second area A2). Hereinafter, in FIGS. 8A and 8B, for the convenience of explanation, the first-second area A1-2 may be referred to as the first area A1, and the second-first area A2-1 may be referred to as the second area A2.

Referring to FIGS. 8A and 8B, at least one inorganic layer may be formed on an upper surface of a base layer BL. The inorganic layer may include at least one of aluminum oxide, titanium oxide, silicon oxide, silicon nitride, silicon oxynitride, zirconium oxide, or hafnium oxide. The inorganic layer may be formed in multiple layers. The inorganic layers formed in multiple layers may form a barrier layer and/or a buffer layer. The display panel DP may include a buffer layer BFL.

The buffer layer BFL may increase an adhesion between the base layer BL and a semiconductor pattern. The buffer layer BFL may include at least one of silicon oxide, silicon nitride, or silicon oxynitride. As an example, the buffer layer BFL may have a stack structure in which a silicon oxide layer and a silicon nitride layer are alternately stacked with each other.

The semiconductor pattern may be located on the buffer layer BFL (as used herein, “located on” may mean “above”). The semiconductor pattern may include polycrystalline silicon, although it should not be limited thereto or thereby. The semiconductor pattern may include amorphous silicon, low-temperature polycrystalline silicon, or oxide semiconductor.

FIGS. 8A and 8B show only a portion of the semiconductor pattern, and the semiconductor pattern may be further located in other areas. The semiconductor pattern may be arranged with a specific rule over pixels. The semiconductor pattern may have different electrical properties depending on whether it is doped or not. The semiconductor pattern may include a first region with high conductivity and a second region with low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or may be a region doped at a concentration lower than the first region.

The first region may have a conductivity that is greater than that of the second region, and may substantially serve as an electrode or a signal line. The second region may substantially correspond to an active area (or a channel) of a transistor. In other words, a portion of the semiconductor pattern may be the active area of the transistor, another portion of the semiconductor pattern may be a source or a drain of the transistor, and the other portion of the semiconductor pattern may be a connection electrode or a connection signal line.

Each of the pixels may include a pixel circuit and a light-emitting element. The pixel circuit may include a plurality of transistors and at least one capacitor. FIGS. 8A and 8B show one transistor 100PC among the transistors as a representative example.

A source area SC, an active area AL, and a drain area DR of the transistor 100PC may be formed from the semiconductor pattern. The source area SC and the drain area DR may extend in opposite directions to each other from the active area AL in a cross-section. FIGS. 8A and 8B show a portion of a connection signal line SCL formed from the semiconductor pattern. In one or more embodiments, the connection signal line SCL may be electrically connected to the drain area DR of the transistor 100PC in a plane.

A first insulating layer 10 may be located on the buffer layer BFL. The first insulating layer 10 may commonly overlap the pixels, and may cover the semiconductor pattern. The first insulating layer 10 may be an inorganic layer and/or an organic layer, and may have a single-layer or multi-layer structure. The first insulating layer 10 may include at least one of aluminum oxide, titanium oxide, silicon oxide, silicon nitride, silicon oxynitride, zirconium oxide, or hafnium oxide. The first insulating layer 10 may have a single-layer structure of a silicon oxide layer. Not only the first insulating layer 10, but also an insulating layer of a circuit layer DP_CL described later may be an inorganic layer and/or an organic layer, and may have a single-layer or multi-layer structure. The inorganic layer may include at least one of the above-mentioned materials, although it should not be limited thereto.

A gate GT of each of the transistors 100PC may be located on the first insulating layer 10. The gate GT may be a portion of a metal pattern. The gate GT may overlap the active area AL. The gate GT may be used as a mask in a process of doping the semiconductor pattern.

A second insulating layer 20 may be located on the first insulating layer 10 and may cover the gate GT. The second insulating layer 20 may commonly overlap the pixels. The second insulating layer 20 may be an inorganic layer and/or an organic layer and may have a single-layer or multi-layer structure. The second insulating layer 20 may include at least one of silicon oxide, silicon nitride, or silicon oxynitride. The second insulating layer 20 may have a multi-layer structure of a silicon oxide layer and a silicon nitride layer.

A third insulating layer 30 may be located on the second insulating layer 20. The third insulating layer 30 may have a single-layer structure or a multi-layer structure. As an example, the third insulating layer 30 may have the multi-layer structure of a silicon oxide layer and a silicon nitride layer.

A first connection electrode CNE1 may be located on the third insulating layer 30. The first connection electrode CNE1 may be connected to the connection signal line SCL via a contact hole CNT-1 defined through the first, second, and third insulating layers 10, 20, and 30.

A fourth insulating layer 40 may be located on the third insulating layer 30. The fourth insulating layer 40 may have a single-layer structure of a silicon oxide layer. A fifth insulating layer 50 may be located on the fourth insulating layer 40. The fifth insulating layer 50 may be an organic layer.

A second connection electrode CNE2 may be located on the fifth insulating layer 50. The second connection electrode CNE2 may be connected to the first connection electrode CNE1 via a contact hole CNT-2 defined through the fourth insulating layer 40 and the fifth insulating layer 50.

A sixth insulating layer 60 may be located on the fifth insulating layer 50 and may cover the second connection electrode CNE2. The sixth insulating layer 60 may be an organic layer.

An element layer DP_ED may be located on the circuit layer DP_CL. The third-first light-emitting element ED1-G1 (refer to FIG. 7) and the second light-emitting element ED1-R (refer to FIG. 7) included in the first group of light-emitting elements ED1 may be located in the element layer DP_ED overlapping the first area A1, and the third-first light-emitting element ED2-G1 (refer to FIG. 7) and the second light-emitting element ED2-R (refer to FIG. 7) included in the second group of light-emitting elements ED2 may be located in the element layer DP_ED overlapping the second area A2.

The third-first light-emitting element ED1-G1 (refer to FIG. 7) and the second light-emitting element ED1-R (refer to FIG. 7) may be referred to as light-emitting elements WOLG1 and WOLR, respectively, in FIG. 8A, and the third-first light-emitting element ED2-G1 (refer to FIG. 7) and the second light-emitting element ED2-R (refer to FIG. 7) may be referred to as light-emitting elements WOLG1 and WOLR, respectively, in FIG. 8B. The light-emitting elements WOLG1 and WOLR of FIGS. 8A and 8B may include a first electrode AE, a light-emitting pattern EL, and a second electrode CE. The second electrode CE may be formed over the entire first and second areas A1 and A2. Accordingly, the second electrode CE may be a common electrode.

The first electrode AE may be located on the sixth insulating layer 60. The first electrode AE may be connected to the second connection electrode CNE2 via a contact hole CNT-3 defined through the sixth insulating layer 60.

A pixel definition layer 70 may be located on the sixth insulating layer 60 and may cover a portion of the first electrode AE. A display opening 70-OP may be defined through the pixel definition layer 70, and at least a portion of the first electrode AE may be exposed through the display opening 70-OP of the pixel definition layer 70.

The light-emitting pattern EL may be located in the display opening 70-OP. The light-emitting pattern EL may be individually patterned for each pixel. The light-emitting patterns EL may emit different colors of light. However, the present disclosure should not be limited thereto or thereby, and the light-emitting patterns EL may be interconnected, and may be commonly included in the light-emitting elements. In this case, the light-emitting pattern EL may provide a blue light or a white light.

The second electrode CE may be located on the light-emitting patterns EL. The second electrode CE may have an integral shape and may be commonly included in the pixels.

A hole control layer may be located between the first electrodes AE and the light-emitting patterns EL. The hole control layer may include a hole transport layer and may further include a hole injection layer. An electron control layer may be located between the light-emitting patterns EL and the second electrode CE. The electron control layer may include an electron transport layer and may further include an electron injection layer. The hole control layer and the electron control layer may be commonly formed in the plural pixels using an open mask or an inkjet process.

The display device DD may include a protective layer CPL located on the second electrode CE. The protective layer CPL may be formed over the entire first and second areas A1 and A2. Accordingly, the protective layer CPL may be a common electrode. The protective layer CPL may protect components included in the light-emitting elements in subsequent processes. The protective layer CPL may have a refractive index of about 2.0.

A thin film encapsulation layer TFE may be located on the element layer DP_ED. The thin film encapsulation layer TFE may cover the light-emitting elements. The thin film encapsulation layer TFE may include a first inorganic layer 141, an organic layer 142, and a second inorganic layer 143, which are sequentially stacked, although layers forming the thin film encapsulation layer TFE should not be limited thereto or thereby. The first inorganic layer 141 and the second inorganic layer 143 may protect the element layer DP_ED from moisture and oxygen, and the organic layer 142 may protect the element layer DP_ED from a foreign substance, such as dust particles. The first and second inorganic layers 141 and 143 may include an inorganic material. For example, each of the first and second inorganic layers 141 and 143 may include one of silicon nitride, silicon oxynitride, silicon oxide, titanium oxide, or aluminum oxide. The organic layer 142 may include an acrylic-based organic material, although it should not be particularly limited.

An input-sensing layer ISL may be located directly on the display panel DP. The input-sensing layer ISL may be formed on the display panel DP through successive processes. The input-sensing layer ISL may be referred to as a sensor, or an input-sensing panel. The input-sensing layer ISL may include a sensor base layer 210, a first conductive layer 220, a first sensor insulating layer 230, a second conductive layer 240, and a second sensor insulating layer 250.

The sensor base layer 210 may be located directly on the display panel DP. The sensor base layer 210 may be an inorganic layer that includes at least one of silicon nitride, silicon oxynitride, or silicon oxide. Alternatively, the sensor base layer 210 may be an organic layer that includes an epoxy-based resin, an acrylic-based resin, or an imide-based resin. The sensor base layer 210 may have a single-layer structure or a multi-layer structure of layers stacked one on another in the third direction DR3.

Each of the first conductive layer 220 and the second conductive layer 240 may have a single-layer structure or a multi-layer structure of layers stacked in the third direction DR3.

The conductive layer having the single-layer structure may include a metal layer or a transparent conductive layer. The metal layer may include molybdenum (Mo), silver (Ag), titanium (Ti), copper (Cu), aluminum (Al), or alloys thereof. The transparent conductive layer may include a transparent conductive oxide, such as indium tin oxide (ITO), indium zinc oxide (IZO), zinc oxide (ZnO), indium zinc tin oxide (IZTO), or the like. In addition, the transparent conductive layer may include a conductive polymer such as poly(3,4-ethylenedioxythiophene) (PEDOT), a metal nanowire, a graphene, or the like.

The conductive layer having the multi-layer structure may include metal layers. The metal layers may have, for example, a three-layer structure of titanium/aluminum/titanium. The conductive layer having the multi-layer structure may include at least one metal layer and at least one transparent conductive layer.

The first sensor insulating layer 230 may be located between the first conductive layer 220 and the second conductive layer 240. The first sensor insulating layer 230 may include an inorganic layer. The inorganic layer may include at least one of aluminum oxide, titanium oxide, silicon oxide, silicon nitride, silicon oxynitride, zirconium oxide, or hafnium oxide.

The first sensor insulating layer 230 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The second sensor insulating layer 250 may be located on the first sensor insulating layer 230 and may cover the second conductive layer 240. The second conductive layer 240 may include a conductive pattern. The second sensor insulating layer 250 may cover the conductive pattern and may reduce or eliminate the probability of damage to the conductive pattern during subsequent processes. The second sensor insulating layer 250 may include an inorganic material. As an example, the second sensor insulating layer 250 may include silicon nitride, although it should not be particularly limited. According to one or more embodiments, the second sensor insulating layer 250 may be omitted.

An anti-reflective layer ARL may be located on the input-sensing layer ISL. The anti-reflective layer ARL may include a first light-blocking layer 310, color filter layer 320, a cover inorganic layer 330, a planarization layer 340, a second light-blocking layer 350, and an overcoating layer 360.

The first light-blocking layer 310, which will be described with reference to FIGS. 8A and 8B, may correspond to the first light-blocking layer BM1 described with reference to FIG. 7. Accordingly, the opening BM1-OP of the first light-blocking layer BM1 of FIG. 7 may correspond to openings OP1 and OP2 of the first light-blocking layer 310 of FIGS. 8A and 8B.

Referring to FIGS. 7 and 8A, a first opening OP1 may correspond to the first group of light-emitting elements ED1, and the first opening OP1 may overlap the display opening 70-OP described later. The first opening OP1 may be defined within the display opening 70-OP. Referring to FIGS. 7 and 8B, a second opening OP2 may correspond to the second group of light-emitting elements ED2, and the second opening OP2 may overlap the display opening 70-OP described later. Similarly, the second opening OP2 may be defined within the display opening 70-OP.

According to the present disclosure, the first light-blocking layer 310 may be commonly located in the first area A1 and the second area A2. The first light-blocking layer 310 may overlap the conductive pattern of the second conductive layer 240. The first light-blocking layer 310 may be located directly on the second sensor insulating layer 250. The first light-blocking layer 310 may reduce or prevent external light reflection caused by the second conductive layer 240.

Materials for the first light-blocking layer 310 should not be particularly limited as long as the materials absorb lights. The first light-blocking layer 310 may have a black color, and the first light-blocking layer 310 may include a black coloring agent. The black coloring agent may include a black dye or a black pigment. The black coloring agent may include a metal material, such as carbon black, chromium, or an oxide thereof.

As described above, the first and second openings OP1 and OP2 may be defined through the first light-blocking layer 310. Referring to FIGS. 7, 8A, and 8B, each of the first openings OP1 defined in the first areas A1 and the second openings OP2 defined in the second areas A2 may have a circular shape. The first openings OP1 and the second openings OP2 may have the same size. However, the present disclosure should not be limited thereto or thereby, among the sizes of openings that transmit the light of the corresponding color, the size of the opening defined in the first area A1 may be greater than the size of the opening defined in the second area A2.

The first openings OP1 and the second openings OP2 may have the same shape as the shape of the display openings 70-OP defined through the pixel definition layer 70 when viewed in the plane, although the present disclosure should not be particularly limited.

As shown in FIG. 8A, transmission areas WPXAG1 and WPXAR, through which is transmitted the light emitted from the first-second group of light-emitting elements ED1-2 (refer to FIG. 6B), may be defined by the openings OP1 defined in the first area A1 of the first light-blocking layer 310. FIG. 8A shows only the third-first light-emitting element ED1-G1 (refer to FIG. 6B) and the second light-emitting element ED1-R (refer to FIG. 6B), although the above descriptions may be equally applied to the first light-emitting element ED1-B (refer to FIG. 6B) and the third-second light-emitting element ED1-G2 (refer to FIG. 6B).

As shown in FIG. 8B, transmission areas NPXAG1 and NPXAR, through which is transmitted the light emitted from the second-first group of light-emitting elements ED2-1 (refer to FIG. 6B), may be defined by the openings OP2 defined in the second area A2 of the first light-blocking layer 310. FIG. 8B shows only the third-first light-emitting element ED2-G1 (refer to FIG. 6B) and the second light-emitting element ED2-R (refer to FIG. 6B), although the above descriptions may be equally applied to the first light-emitting element ED2-B (refer to FIG. 6B) and the third-second light-emitting element ED2-G2 (refer to FIG. 6B). The first and the second openings OP1 and OP2 may be defined by side surfaces of the first light-blocking layer 310.

The color filter layer 320 shown in FIG. 8A may include a first-first color filter W320G1 and a first-second color filter W320R, which are located in the first area A1. Each of the first-first color filter W320G1 and the first-second color filter W320R may cover the opening OP1 defined in the first area A1. The first-first color filter W320G1 may transmit the light emitted from the third-first light-emitting element ED1-G1 (refer to FIG. 6B), and the first-second color filter W320R may transmit the light emitted from the second light-emitting element ED1-R (refer to FIG. 6B). The above descriptions may be applied to the color filter layer 320 shown in FIG. 8B, and thus, repeated detailed descriptions of the color filter layer 320 shown in FIG. 8B will be omitted.

The cover inorganic layer 330 may be commonly located in the first area A1 and the second area A2. The cover inorganic layer 330 may cover the color filter layer 320. The cover inorganic layer 330 may protect the color filter layer 320 and the first light-blocking layer 310 from moisture and oxygen. The cover inorganic layer 330 may include a silicon nitride layer, a silicon oxynitride layer, a silicon oxide layer, a titanium oxide layer, or an aluminum oxide layer.

The planarization layer 340 may be commonly located in the first area A1 and the second area A2. The planarization layer 340 may cover the first light-blocking layer 310 and the color filter layer 320. The planarization layer 340 may include an organic material, and may provide a flat surface on an upper surface of the planarization layer 340. The planarization layer 340 may be formed by an inkjet process. According to one or more embodiments, the planarization layer 340 may be omitted.

The overcoating layer 360 may be commonly located in the first area A1 and the second area A2. The overcoating layer 360 may cover the planarization layer 340. The overcoating layer 360 may be located on the planarization layer 340 in the first area A1. In detail, because the second light-blocking layer 350 is not located in the first area A1, a lower surface of the overcoating layer 360 may be entirely in contact with an upper surface of the planarization layer 340 in the first area A1.

As shown in FIG. 8B, the anti-reflective layer ARL may include the second light-blocking layer 350 located only in the second area A2. The second light-blocking layer 350 may be located on the planarization layer 340, and may be covered by the overcoating layer 360. The second light-blocking layer 350 may correspond to the second light-blocking layer BM2 described in FIG. 7.

According to the present disclosure, the first light-blocking layer BM1 may be located throughout the first areas A1 and the second areas A2. The second light-blocking layer BM2 may be located only in the second areas A2. The second light-blocking layer 350 may include substantially the same material as the first light-blocking layer 310. Accordingly, the second light-blocking layer 350 may include a black coloring agent for reducing or preventing the external light reflection and absorbing the light.

When comparing FIG. 8A and FIG. 8B, the first area A1 may include the first light-blocking layer 310 through which the first openings OP1 are defined, and may omit the second light-blocking layer 350. Therefore, in the first mode and the second mode, the lights emitted from the light-emitting elements WOLG1 and WOLR may be perceived by the user and external observers viewing from a high angle.

On the other hand, the second area A2 may include the first light-blocking layer 310 through which the second openings OP2 are defined and the second light-blocking layer 350 through which fourth openings OP4 are defined. As described above, in the first mode, the light emitted at a low angle from the light-emitting elements WOLG1 and WOLR may not be perceived by external observers.

Accordingly, compared to a structure having only the first light-blocking layer 310, when the second (e.g., additional) light-blocking layer 350 is formed together with the first light-blocking layer 310, a narrower viewing angle may be achieved. As the narrower viewing angle is formed, a stronger, or more secure, private mode may be provided, and thus, a privacy protection of the display device DD may be enhanced.

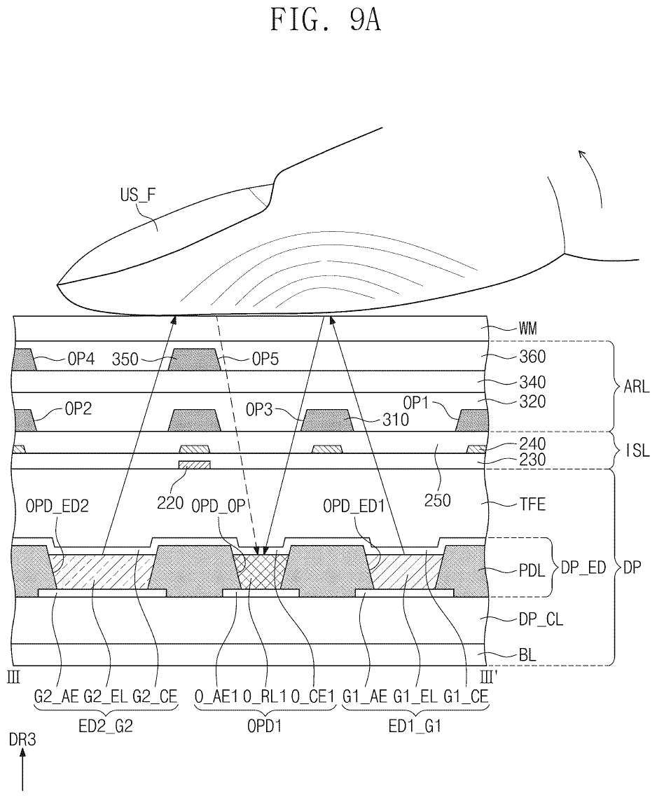

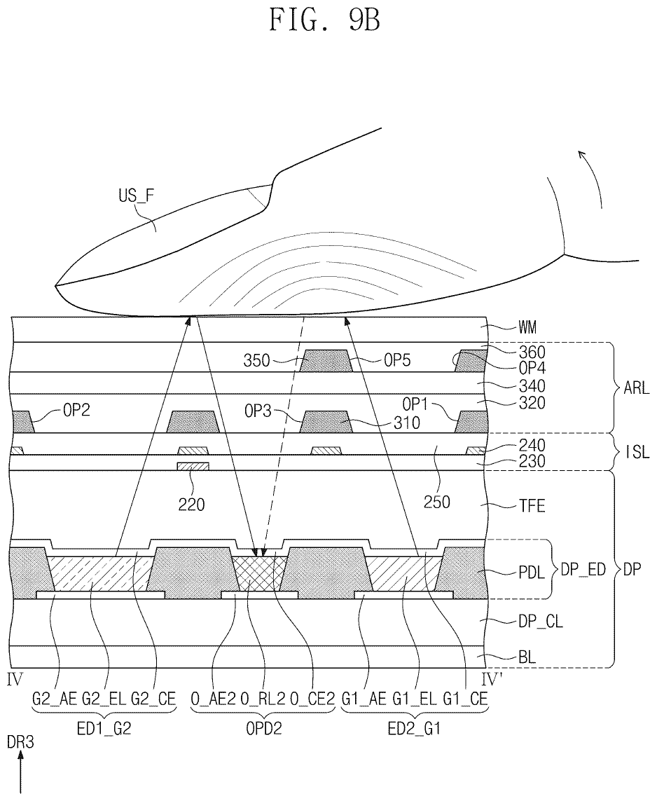

FIG. 9A is a cross-sectional view taken along the line III-III′ of FIG. 7, and FIG. 9B is a cross-sectional view taken along the line IV-IV′ of FIG. 7. Descriptions of the elements assigned with the aforementioned reference numerals are omitted.

Referring to FIGS. 9A and 9B, the element layer DP_ED may include the light-emitting elements ED1 and ED2 and the pixel definition layer PDL. In FIG. 9A, the first light-sensing element OPD1 may be located between the third-second light-emitting element ED2-G2 of the second group of light-emitting elements ED2 and the third-first light-emitting element ED1-G1 of the first group of light-emitting elements ED1. In FIG. 9B, the second light-sensing element OPD2 may be located between the third-second light-emitting element ED1-G2 of the first group of light-emitting elements ED1 and the third-first light-emitting element ED2-G1 of the second group of light-emitting elements ED2. The first light-sensing element OPD1 and the second light-sensing element OPD2 may be electrically connected to each other. Hereinafter, descriptions on the elements with reference to FIG. 9A may be equally applied to the same elements shown in FIG. 9B.

Referring to FIG. 9A, a green light-emitting layer G2_EL may be located on a first electrode G2_AE of the second group of light-emitting elements ED2, and a green light-emitting layer G1_EL may be located on a first electrode G1_AE of the first group of light-emitting elements ED1. A photoelectric conversion layer O_RL1 may be located on a first electrode O_AE1 of the first light-sensing element OPD1. The photoelectric conversion layer O_RL1 may include an organic photosensitive material (e.g., a photosensitive semiconductor material). A second electrode layer CE may be commonly located on the green light-emitting layers G1_EL, G2_EL and the photoelectric conversion layer O_RL1. The second electrode layer CE may include second electrodes G1_CE and G2_CE of the third-first light-emitting element ED1-G1 and the third-second light-emitting element ED2-G2, and a second electrode O_CE1 of the first light-sensing element OPD1. That is, the photoelectric conversion layer O_RL1 may be located between the first electrode O_AE1 and the second electrode O_CE1.

The input-sensing layer ISL located on the thin film encapsulation layer TFE may include the first conductive layer 220, the first sensor insulating layer 230, the second conductive layer 240, and the second sensor insulating layer 250. According to the present disclosure, the first conductive layer 220 may be located directly on the thin film encapsulation layer TFE, although the present disclosure should not be limited thereto or thereby. The input-sensing layer ISL may further include a base-insulating layer located between the first conductive layer 220 and the thin film encapsulation layer TFE. In this case, the thin film encapsulation layer TFE may be covered by the base-insulating layer, and the first conductive layer 220 may be located on the base-insulating layer. As an example, the base-insulating layer may include an inorganic layer.

The first sensor insulating layer 230 may cover the first conductive layer 220. The first sensor insulating layer 230 may include an inorganic layer. The second conductive layer 240 may be located on the first sensor insulating layer 230. The first and second conductive layers 220 and 240 may include a plurality of conductive patterns. The conductive patterns may define an input-sensing electrode. The second conductive layer 240 may include two types of input-sensing electrodes, and the first conductive layer 220 may correspond to a bridge pattern connecting one of the two types of input-sensing electrodes. Sensor patterns may be connected to the bridge pattern via a contact hole defined through the first sensor insulating layer 230.

The input-sensing layer ISL may include the first and second conductive layers 220 and 240, although the present disclosure should not be limited thereto or thereby. As an example, the input-sensing layer ISL may include only one of the first or second conductive layers 220 or 240.

The second sensor insulating layer 250 may be located on the second conductive layer 240. The second sensor insulating layer 250 may include an organic insulating material. The second sensor insulating layer 250 may protect the first and second conductive layers ICL1 and ICL2 from moisture and oxygen, and may protect the first and second conductive layers ICL1 and ICL2 from a foreign substance. In one or more embodiments, the anti-reflective layer ARL may be further formed on the second sensor insulating layer 250.

The anti-reflective layer ARL may include the first light-blocking layer 310, the color filter layer 320, the planarization layer 340, the second light-blocking layer 350, and the overcoating layer 360.

The first opening OP1 corresponding to the first group of light-emitting elements ED1, the second opening OP2 corresponding to the second group of light-emitting elements ED2, and a third opening OP3 corresponding to the light-sensing elements OPD1 and OPD2 may be defined through the first light-blocking layer 310. In addition, the fourth opening OP4 corresponding to the second opening OP2 and a fifth opening OP5 corresponding to the third opening OP3 may be further defined through the second light-blocking layer 350.

Each of the first opening OP1 to the fourth opening OP4 may have a circular shape or an oval shape. In addition, the fifth opening OP5 may also have the circular shape or the oval shape, although it should not be limited thereto or thereby. As an example, the second light-blocking layer 350 may include light-blocking patterns to provide the fifth opening OP5 with a ring shape.

As shown in FIG. 9A, when the user's finger US_F is in contact with the window WM, the lights respectively emitted from the third-second light-emitting element ED2-G2 of the second group of light-emitting elements ED2, and the third-first light-emitting element ED1-G1 of the first group of light-emitting elements ED1, may be reflected by the user's fingerprint. In this case, the light emitted from the third-second light-emitting element ED2-G2 of the second group of light-emitting elements ED2 may be partially blocked and partially reflected by the second light-blocking layer 350, and then may be incident to the photoelectric conversion layer O_RL1. On the other hand, the light emitted from the third-first light-emitting element ED1-G1 of the first group of light-emitting elements ED1 may be totally reflected because the second light-blocking layer 350 is omitted, and the reflected light may be totally incident to the photoelectric conversion layer O_RL1 of the first light-sensing element OPD1.

Similarly, as shown in FIG. 9B, when the user's finger US_F is in contact with the window WM, the lights respectively emitted from the third-second light-emitting element ED1-G2 of the first group of light-emitting elements ED1, and the third-first light-emitting element ED2-G1 of the second group of light-emitting elements ED2, may be reflected by the user's fingerprint. In this case, the light emitted from the third-second light-emitting element ED1-G2 of the first group of light-emitting elements ED1 may be totally reflected because the second light-blocking layer 350 is not located, and the reflected light may be totally incident to the photoelectric conversion layer O_RL2. On the other hand, the light emitted from the third-first light-emitting element ED2-G1 of the second group of light-emitting elements ED2 may be partially blocked and partially reflected by the second light-blocking layer 350, and the reflected light may be incident to the photoelectric conversion layer O_RL2 of the second light-sensing element OPD2.

That is, because the reflected light is totally incident, except for the light that is blocked, both the first light-sensing element OPD1 and the second light-sensing element OPD2 may receive a substantially uniform amount of light. In addition, all light-sensing elements may receive the same amount of light regardless of their positions, and thus, noise light may be reduced, and deviation in the amount of light may be further reduced. Accordingly, light-sensing elements may more clearly receive information about ridges and valleys of the user's fingerprint entering the light-sensing elements OPD, and may obtain more accurate information about the fingerprint information of the finger in contact with the window WM. As a result, the efficiency and reliability of fingerprint detection by the light-sensing elements OPD may be further improved.

FIG. 10 is an enlarged plan view of a portion of a display panel in a second operation mode according to one or more embodiments of the present disclosure. A second light-blocking layer BM2 may be substantially the same as that shown in FIG. 7, except that the second light-blocking layer BM2 further includes bridge patterns connecting the light-blocking patterns described in FIG. 9, and thus, details thereof will be omitted. As the second light-blocking layer BM2 of FIG. 10 further includes the bridge patterns, the external light may be absorbed more evenly, and the effect in reflecting the external light may be improved.

Although the embodiments of the present disclosure have been described, it is understood that the present disclosure should not be limited to these embodiments, but various changes and modifications can be made by one ordinary skilled in the art within the spirit and scope of the present disclosure as hereinafter claimed. Therefore, the disclosed subject matter should not be limited to any single embodiment described herein, and the scope of the present disclosure shall be determined according to the attached claims, with functional equivalents thereof to be included therein.

What is claimed is:

1. A display device comprising:
a window; and
a display module below the window, and comprising:
a base layer comprising a first area and a second area comprising a light-emitting area and a peripheral area;
a first group of light-emitting elements in the light-emitting area of the first area, and configured to be deactivated during a first operation mode, and to be activated during a second operation mode;
a second group of light-emitting elements in the light-emitting area of the second area, and configured to be activated during the first operation mode and the second operation mode;
a first light-sensing element between the first group of the light-emitting elements and the second group of the light-emitting elements;
a first light-blocking layer defining a first opening corresponding to the first group of the light-emitting elements, a second opening corresponding to the second group of the light-emitting elements, and a third opening corresponding to the first light-sensing element; and
a second light-blocking layer above the first light-blocking layer, apart from the first area in plan view, overlapping the second area, and defining a fourth opening corresponding to the second opening.

2. The display device of claim 1, wherein the first group of the light-emitting elements and the second group of the light-emitting elements comprise:
a first light-emitting element configured to emit a first color light;
a second light-emitting element spaced apart from the first light-emitting element in a first direction, and configured to emit a second color light;
a third-first light-emitting element configured to emit a third color light; and
a third-second light-emitting element configured to emit the third color light, and spaced apart from the third-first light-emitting element in a second direction crossing the first direction.

3. The display device of claim 2, wherein the first color light is a blue light, the second color light is a red light, and the third color light is a green light.

4. The display device of claim 2, wherein the third-first light-emitting element is spaced apart from the first light-emitting element in a diagonal direction crossing the first direction and the second direction, and
wherein the third-second light-emitting element is spaced apart from the second light-emitting element in the diagonal direction.

5. The display device of claim 2, wherein the first group of the light-emitting elements is spaced apart from the second group of the light-emitting elements in a diagonal direction crossing the first direction and the second direction.

6. The display device of claim 2, wherein the first light-sensing element is between the third-first light-emitting element of the first group of the light-emitting elements and the third-second light-emitting element of the second group of the light-emitting elements in the first direction.

7. The display device of claim 2, wherein the first light-sensing element is between the second light-emitting element of the first group of the light-emitting elements and the first light-emitting element of the second group of the light-emitting elements in the second direction.

8. The display device of claim 2, wherein the first light-emitting element, the second light-emitting element, the third-first light-emitting element, and the third-second light-emitting element comprise a first electrode, a second electrode, and a light-emitting pattern between the first electrode and the second electrode, and
wherein the display module comprises a pixel definition layer defining display openings overlapping the first opening and the second opening and through which at least a portion of the first electrodes is exposed, the light-emitting patterns respectively being in the display openings.

9. The display device of claim 8, wherein the first light-sensing element comprises a photoelectric conversion layer between a first electrode and a second electrode.

10. The display device of claim 2, further comprising a second light-sensing element at a same layer as the first light-sensing element,
wherein the first group of the light-emitting elements comprises a first-first group of light-emitting elements and a first-second group of light-emitting elements arranged in the first direction from the first-first group of the light-emitting elements,
wherein the second group of the light-emitting elements comprises a second-first group of light-emitting elements and a second-second group of light-emitting elements arranged in the second direction from the second-first group of the light-emitting elements,
wherein the first light-sensing element is between the first-first group of the light-emitting elements and the second-first group of the light-emitting elements, and
wherein the second light-sensing element is between the first-second group of the light-emitting elements and the second-second group of the light-emitting elements.

11. The display device of claim 10, wherein the first light-sensing element is electrically connected to the second light-sensing element.

12. The display device of claim 1, wherein the display module comprises:
a color filter layer covering the first opening, the second opening, and the third opening;
a thin film encapsulation layer covering the first group of the light-emitting elements, the second group of the light-emitting elements, and the first light-sensing element; and
an insulating layer above the thin film encapsulation layer.

13. The display device of claim 12, further comprising an input-sensing electrode between the thin film encapsulation layer and the insulating layer.

14. The display device of claim 1, wherein the first opening, the second opening, the third opening, and the fourth opening have a circular shape or an oval shape.

15. The display device of claim 1, wherein the second light-blocking layer defines a fifth opening corresponding to the third opening.

16. The display device of claim 15, wherein the second light-blocking layer comprises light-blocking patterns having a ring shape defining the fifth opening.

17. The display device of claim 16, wherein the second light-blocking layer further comprises bridge patterns connecting the light-blocking patterns.

18. An electronic device comprising:
a window;
a housing coupled with the window; and
a display module between the window and the housing, and comprising:
a base layer comprising a first area and a second area comprising a light-emitting area and a peripheral area;
a first group of light-emitting elements in the light-emitting area of the first area, and configured to be deactivated during a first operation mode, and to be activated during a second operation mode;
a second group of light-emitting elements in the light-emitting area of the second area, and configured to be activated during the first operation mode and the second operation mode;
a first light-sensing element between the first group of the light-emitting elements and the second group of the light-emitting elements;
a first light-blocking layer defining a first opening corresponding to the first group of the light-emitting elements, a second opening corresponding to the second group of the light-emitting elements, and a third opening corresponding to the first light-sensing element; and
a second light-blocking layer above the first light-blocking layer, spaced from the first area in plan view, overlapping the second area, and defining a fourth opening corresponding to the second opening.

19. The electronic device of claim 18, wherein the first group of the light-emitting elements and the second group of the light-emitting elements comprise:
a first light-emitting element configured to emit a first color light;
a second light-emitting element spaced apart from the first light-emitting element in a first direction, and configured to emit a second color light;
a third-first light-emitting element configured to emit a third color light; and
a third-second light-emitting element configure to emit the third color light, and spaced apart from the third-first light-emitting element in a second direction crossing the first direction.

20. The electronic device of claim 19, wherein the first group of the light-emitting elements is spaced apart from the second group of the light-emitting elements in a diagonal direction crossing the first direction and the second direction.
